(19) United States
(12) Patent Application Publication
(10) Pub. No.: US 2019/0245107 A1
(43) Pub. Date: Aug. 8, 2019

(54) SOLAR CELL ELEMENT

(71) Applicant: KYOCERA CORPORATION, Kyoto (JP)

(72) Inventors: Akira MURAO, Moriyama-shi (JP); Norihiko MATSUSHIMA, Yasu-shi (JP)

(21) Appl. No.: 16/388,631

(22) Filed: Apr. 18, 2019

Related U.S. Application Data
(63) Continuation of application No. PCT/JP2017/038683, filed on Oct. 26, 2017.

(30) Foreign Application Priority Data
Oct. 26, 2016 (JP) 2016-209570

(51) Int. Cl. H01L 31/061; H01L 31/02; H01L 31/0216; H01L 31/0224; H01L 31/0236; H01L 31/18

(52) U.S. Cl. CPC H01L 31/061; H01L 31/0201; H01L 31/02167; H01L 31/1868; H01L 31/022425; H01L 31/02363; H01L 31/1804; H01L 31/02168

(57) ABSTRACT

The solar cell element comprises a semiconductor substrate with first and second surfaces, a passivation layer, a protective layer positioned on the passivation layer on the second surface, and a collector electrode. The collector electrode includes a first portion on the protective layer, and a second portion connected to the second surface in a plurality of hole rows each including holes that penetrate the passivation layer and the protective layer and are arranged along a first direction. When first and second hole rows adjacent in a second direction that intersects with the first direction are viewed in a plane perspective facing the second direction, the second hole row includes a third hole that overlaps a gap between first and second holes in a mutually adjacent state in the first hole row and further overlaps a part of at least one of the first and second holes.

### CROSS-REFERENCE TO RELATED APPLICATIONS

The present application is a continuation based on PCT Application No. PCT/JP2017/038683 filed on Oct. 26, 2017, which claims the benefit of Japanese Application No. 2016-209570, filed on Oct. 26, 2016. PCT Application No. PCT/JP2017/038683 is entitled “PHOTOVOLTAIC CELL ELEMENT”, and Japanese Application No. 2016-209570 is entitled “PHOTOVOLTAIC CELL ELEMENT”. The contents of which are incorporated by reference herein in their entirety.

### FIELD

Embodiments of the present disclosure relate generally to solar cell elements.

### BACKGROUND

Solar cell elements include a solar cell element of a passivated emitter and rear cell (PERC) type. A PERC type solar cell element has a structure in which a passivation layer, a protective layer, and a collector electrode are stacked in this order on the back surface of a crystalline silicon substrate. Here, the collector electrode is electrically connected to the back surface of the crystalline silicon substrate in a contact hole penetrating the passivation layer and the protective layer.

### SUMMARY

A solar cell element is disclosed.

In one embodiment, a solar cell element comprises a semiconductor substrate, a passivation layer, a protective layer, and a collector electrode. The semiconductor substrate has a first surface and a second surface opposite the first surface. The passivation layer is positioned on the second surface. The protective layer is positioned on the passivation layer. The collector electrode includes a first portion on the protective layer, and a second portion positioned in a state of being connected to the second surface in a plurality of hole rows, each of which includes a plurality of holes that are positioned in a state of penetrating the passivation layer and the protective layer. In each of the hole rows, the plurality of holes are positioned in a state of being arranged along a first direction. Each of the holes includes an elongated portion along the first direction. The plurality of hole rows include a first hole row and a second hole row that are positioned while adjacent to each other in a second direction that is in a state of intersecting with the first direction. The first hole row includes a first hole and a second hole that are positioned in a mutually adjacent state. When the first hole row and the second hole row are viewed in a plane perspective facing the second direction, the second hole row includes a third hole positioned in a state of overlapping a gap between the first hole and the second hole and further positioned in a state of overlapping a part of at least one of the first hole and the second hole.

In one embodiment, a solar cell element comprises a semiconductor substrate, a passivation layer, a protective layer, a collector electrode, and a busbar electrode. The semiconductor substrate has a first surface and a second surface opposite the first surface. The passivation layer is positioned on the second surface. The protective layer is positioned on the passivation layer. The collector electrode includes a first portion on the protective layer, and a second portion positioned in a state of being connected to the second surface in a plurality of hole rows, each of which includes a plurality of holes that are positioned in a state of penetrating the passivation layer and the protective layer. The busbar electrode is positioned on the second surface side while electrically connected to the collector electrode, and has a longitudinal direction along the second surface. In each of the hole rows, the plurality of holes are positioned while arranged along a first direction that is in a state of intersecting with the longitudinal direction. Each of the holes includes an elongated portion along the first direction. The plurality of hole rows are positioned while arranged in a second direction that is in a state of intersecting with the first direction.

### BRIEF DESCRIPTION OF THE DRAWINGS

FIG. 1 illustrates a plan view showing an appearance of a first element surface side of an example of a solar cell element according to each of embodiments.

FIG. 2 illustrates a plan view showing an appearance of a second element surface side of an example of a solar cell element according to a first embodiment.

FIG. 3 illustrates a view showing a virtual cut section of the solar cell element along a line in FIG. 1 and FIG. 2.

FIG. 4 illustrates an enlarged plan perspective view showing a configuration of an example of a first region A1 in FIG. 2.

FIG. 5 illustrates an enlarged plan perspective view showing a configuration of an example of a portion P1 in FIG. 4.

FIG. 6 illustrates a view showing a virtual cut section of a portion along a line VI-VI in FIG. 5.

FIG. 7 illustrates a view showing a configuration of a portion corresponding to a first region A1 of a solar cell element according to a reference example.

FIG. 8 illustrates a flowchart showing an example of a flow of a method for manufacturing the solar cell element.

FIG. 9 illustrates a flowchart showing an example of a flow of a method for manufacturing an insulating paste.

FIGS. 10A to 10E illustrate views each showing an example of a virtual cut section corresponding to the virtual cut section of FIG. 3 in a state on a manufacturing stage of the solar cell element. FIG. 10F illustrates a view showing an example of a virtual cut section in a state where the solar cell element has been manufactured.

FIG. 11 illustrates a plan view showing an appearance of a second element surface side of an example of a solar cell element according to a second embodiment.

FIG. 12 illustrates a view showing an example of a distribution of carrier movement directions in a second region A2 in FIG. 11.

FIG. 13 illustrates a view showing an example of a distribution of carrier movement directions in a third region A3 in FIG. 2.

FIG. 14 illustrates a view showing an example of a distribution of carrier movement directions in a region corresponding to the second region A2 in a solar cell element according to a modified example of the second embodiment.

FIG. 15 illustrates a view showing an example of a carrier movement path in the second region A2 in FIG. 11.

FIG. 16 illustrates a view showing an example of a carrier movement path in the third region A3 in FIG. 2.

FIG. 17 illustrates an enlarged plan perspective view showing a configuration of an example of a fourth region A4 in FIG. 11.

FIG. 18 illustrates a view showing a virtual cut section of a portion along a line XVIII-XVIII in FIG. 17.

FIG. 19 illustrates a view showing a virtual cut section of a portion along a line XIX-XIX in FIG. 17.

FIG. 20 illustrates an enlarged plan perspective view showing a configuration of an example of a fifth region A5 in FIG. 11.

FIG. 21 illustrates an enlarged plan perspective view showing a configuration of an example of a portion P2 in FIG. 20.

FIG. 22 illustrates a view showing a virtual cut section of a portion along a line XXII-XXII in FIG. 21.

FIG. 23 illustrates a view showing a configuration of a portion corresponding to a fifth region A5 of a solar cell element according to a reference example.

FIG. 24 illustrates a view showing an example of a carrier movement path in a modified example of the third region A3 in FIG. 2.

FIG. 25 illustrates a view showing an example of a carrier movement path in a modified example of the second region A2 in FIG. 11.

FIG. 26 illustrates a view showing a shape of a hole according to a modified example.

FIG. 27 illustrates a view showing a shape of a hole according to a modified example.

FIG. 28 illustrates a view showing a shape of a hole according to a modified example.

### DETAILED DESCRIPTION

The solar cell element includes a PERC type solar cell element. The PERC type solar cell element has a structure in which a passivation layer, a protective layer, and a collector electrode are stacked in this order on the back surface of a crystalline silicon substrate. Here, the collector electrode is electrically connected to the back surface of the crystalline silicon substrate in a contact hole penetrating the passivation layer and the protective layer.

For the PERC type solar cell element having such a configuration, there is room for improvement in improving photoelectric conversion efficiency.

Therefore, the inventors of the present disclosure created a technology capable of improving the power generation efficiency of the PERC type solar cell element.

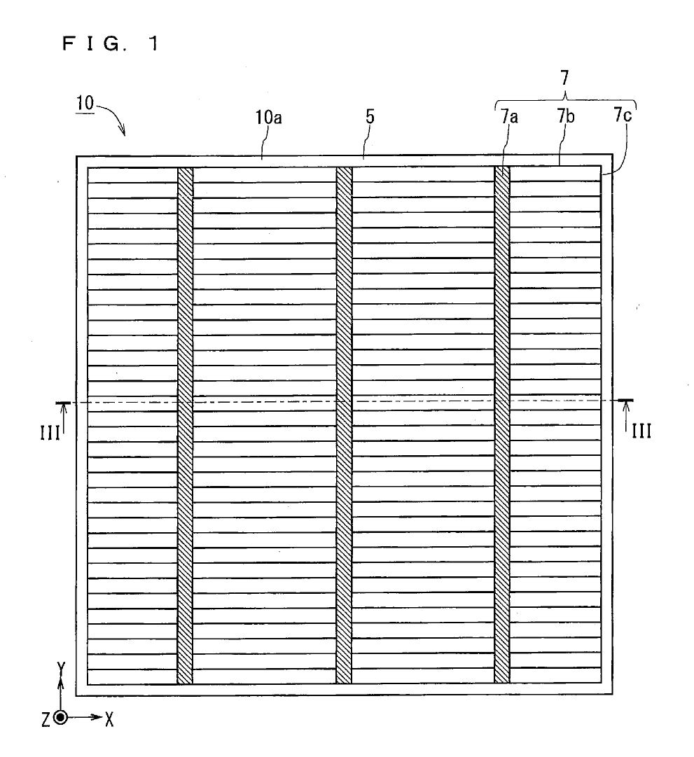

Concerning this, each embodiment will be described below with reference to the drawings. The same reference signs are given to portions having similar structures and functions in the drawings, and description thereof will not be repeated below. The drawings are illustrated schematically. FIGS. 1 to 7 and FIGS. 11A to 28 each illustrate a right-hand XYZ coordinate system. In this XYZ coordinate system, a width direction of a front-surface busbar electrode 7a is taken as a +X direction, a longitudinal direction of the front-surface busbar electrode 7a is taken as a +Y direction, and a direction orthogonal to both the +X direction and the +Y direction is taken as a +Z direction.

### 1. First Embodiment

### 1-1. Schematic Configuration of Solar Cell Element

A schematic configuration of the solar cell element 10 according to the first embodiment will be described with reference to FIGS. 1 to 6. The solar cell element 10 according to the first embodiment is a PERC type solar cell element.

As illustrated in FIGS. 1 to 3, the solar cell element 10 includes a first surface (also referred to as a first element surface) 10a positioned on the front surface side, which is a light receiving surface on which light is mainly incident, and a second surface (also referred to as a second element surface) 10b positioned on the opposite side to the first element surface 10a. In the first embodiment, the first element surface 10a faces the +Z direction and the second element surface 10b faces a −Z direction.

The solar cell element 10 includes, for example, a semiconductor substrate 1, a passivation layer 4, an antireflection layer 5, a protective layer 6, a front-surface electrode 7, and a back-surface electrode 8.

The semiconductor substrate 1 has a first surface 1a and a second surface 1b positioned in a state of facing a direction opposite to the first surface 1a. The first surface 1a is positioned on the first element surface 10a side of the solar cell element 10. In the first embodiment, the first surface 1a faces the +Z direction. The second surface 1b is positioned on the second element surface 10b side of the solar cell element 10. In the first embodiment, the second surface 1b faces the −Z direction. The first surface 1a and the second surface 1b each constitute a plate surface of the semiconductor substrate 1 along the XY plane. The semiconductor substrate 1 has a thickness along the +Z direction.

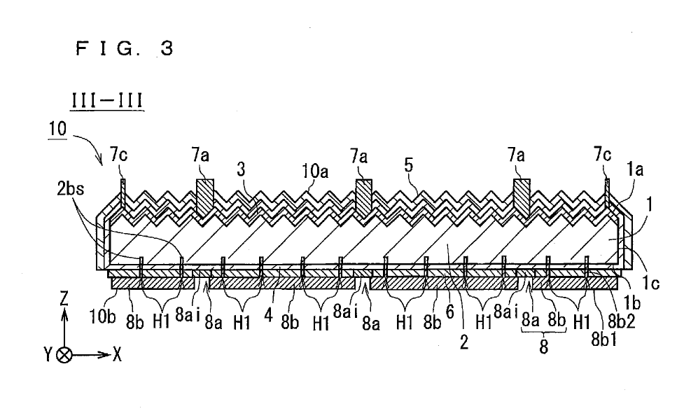

Further, the semiconductor substrate 1 includes a first semiconductor layer 2 and a second semiconductor layer 3. The first semiconductor layer 2 is made of a semiconductor having a first conductivity type. The second semiconductor layer 3 is made of a semiconductor having a second conductivity type opposite to the first conductivity type. The first semiconductor layer 2 is positioned on the second surface 1b side of the semiconductor substrate 1. The second semiconductor layer 3 is positioned in a surface layer portion on the first surface 1a side of the semiconductor substrate 1. In the example of FIG. 3, the second semiconductor layer 3 is positioned on the first semiconductor layer 2.

Here, for example, it is assumed that the semiconductor substrate 1 is a silicon substrate. In this case, a polycrystalline or monocrystalline silicon substrate is adopted as the silicon substrate. The silicon substrate is, for example, a thin substrate having a thickness of 250 μm or less or 150 μm or less. Further, the silicon substrate has, for example, a substantially rectangular plate surface in a plan view. When the semiconductor substrate 1 having such a shape is adopted, the gap between the solar cell elements 10 can be reduced when a solar cell module is manufactured by arranging a plurality of solar cell elements 10.

Further, for example, when the first conductivity type is p-type and the second conductivity type is n-type, the p-type silicon substrate can be formed by, for example, getting impurities such as boron or gallium contained as a dopant element in a polycrystalline or monocrystalline silicon crystal. In this case, by diffusing impurities such as phosphorus serving as the dopant into the surface layer portion on the first surface 1a side of the p-type silicon substrate, the n-type second semiconductor layer 3 can be produced. At this moment, it is possible to form the semiconductor substrate 1 in which the p-type first semiconductor layer 2 and the n-type second semiconductor layer 3 are stacked. As a result, the semiconductor substrate 1 has a pn-junction positioned at an interface between the first semiconductor layer 2 and the second semiconductor layer 3.

As illustrated in FIG. 3, the first surface 1a of the semiconductor substrate 1 may have, for example, a fine uneven structure (texture) for reducing a reflectance of irradiation light. At this time, the height of the projecting portion of the texture is set to, for example, about 0.1 μm to 10 μm. The distance between apexes of the projecting portions positioned in the adjacent state is set to, for example, about 0.1 μm to 20 μm. In the texture, for example, the recess portion may have a substantially spherical shape and the projecting portion may have a pyramid shape. The above-mentioned “height of the projecting portion” means, for example, a distance from a reference line to the apex of the projecting portion in a direction (here, the +Z direction) perpendicular to the reference line, with a straight line passing through the bottom surface of the recess portion taken as the reference line in FIG. 3.

Furthermore, the semiconductor substrate 1 includes a third semiconductor layer 2bs. The third semiconductor layer 2bs is positioned in the surface layer portion on the second surface 1b side of the semiconductor substrate 1. The conductivity type of the third semiconductor layer 2bs may be the same as the conductivity type (p-type in one embodiment) of the first semiconductor layer 2. The concentration of the dopant contained in the third semiconductor layer 2bs is higher than the concentration of the dopant contained in the first semiconductor layer 2. The third semiconductor layer 2bs forms an internal electric field on the second surface 1b side of the semiconductor substrate 1. As a result, in the vicinity of the second surface 1b of the semiconductor substrate 1, recombination of minority carriers generated by photoelectric conversion according to light irradiation in the semiconductor substrate 1 can be reduced. As a result, reduction in photoelectric conversion efficiency hardly occurs. The third semiconductor layer 2bs can be formed by diffusing dopant elements such as aluminum in a surface layer portion on the second surface 1b side of the semiconductor substrate 1, for example. At this time, the concentration of the dopant element contained in the first semiconductor layer 2 is set to about 5×10¹⁵ atoms/cm³ to 1×10¹⁷ atoms/cm³, and the concentration of the dopant element contained in the third semiconductor layer 2bs is set to 1×10¹⁸ atoms/cm³ to 5×10²¹ atoms/cm³. It is sufficient that the third semiconductor layer 2bs is present at the contact portion between a back-surface collector electrode 8b, described later, and the semiconductor substrate 1.

The passivation layer 4 is positioned on at least the second surface 1b of the semiconductor substrate 1. In the first embodiment, the passivation layer 4 is in contact with the second surface 1b of the semiconductor substrate 1. The passivation layer 4 can reduce recombination of minority carriers produced by photoelectric conversion according to light irradiation in the semiconductor substrate 1. As a material of the passivation layer 4, for example, aluminum oxide or the like is adopted. In this case, the passivation layer 4 can be formed by, for example, atomic layer deposition (ALD) method. Here, since the aluminum oxide has a negative fixed charge, minority carriers (in this case, electrons) generated on the second surface 1b side of the semiconductor substrate 1 are moved away from the interface (second surface 1b) between the p-type first semiconductor layer 2 and the passivation layer 4. As a result, recombination of minority carriers in the vicinity of the second surface 1b of the semiconductor substrate 1 can be reduced. This enables improvement in photoelectric conversion efficiency of the solar cell element 10. The thickness of the passivation layer 4 is set to, for example, about 10 nm to 60 nm. The passivation layer 4 may also be positioned on the first surface 1a side of the semiconductor substrate 1, for example. The passivation layer 4 may also be positioned on an end face 1c connecting the first surface 1a and the second surface 1b of the semiconductor substrate 1, for example.

The antireflection layer 5 can reduce the reflectance of light with which the first element surface 10a of the solar cell element 10 is irradiated. As a material of the antireflection layer 5, for example, silicon oxide, aluminum oxide, silicon nitride, or the like can be adopted. The refractive index and the thickness of the antireflection layer 5 are appropriately set to values that enable realization of a condition (also referred to as a low reflection condition) in which the reflectance is low with respect to light in such a wavelength range as to be absorbed by the semiconductor substrate 1 and contributable to power generation among sunlight. For example, the refractive index of the antireflection layer 5 is set to about 1.8 to 2.5, and the thickness of the antireflection layer 5 is set to about 50 nm to 120 nm.

The protective layer 6 is positioned on the passivation layer 4 positioned on the second surface 1b of the semiconductor substrate 1. In the first embodiment, the protective layer 6 covers the passivation layer 4 on the passivation layer 4. Thereby, the protective layer 6 is positioned in a state of protecting the passivation layer 4. As the material of the protective layer 6, for example, silicon oxide, silicon nitride, an insulating resin, or the like is adopted. The protective layer 6 is positioned on the passivation layer 4 so as to have a desired pattern. The protective layer 6 has a plurality of holes H1 penetrating the protective layer 6 in the thickness direction (the +Z direction in this case). For example, the hole H1 may be a hole forming a through hole with its periphery closed along the second surface 1b, or may be a slit-like hole having a periphery along the second surface 1b, at least a part of which is opened.

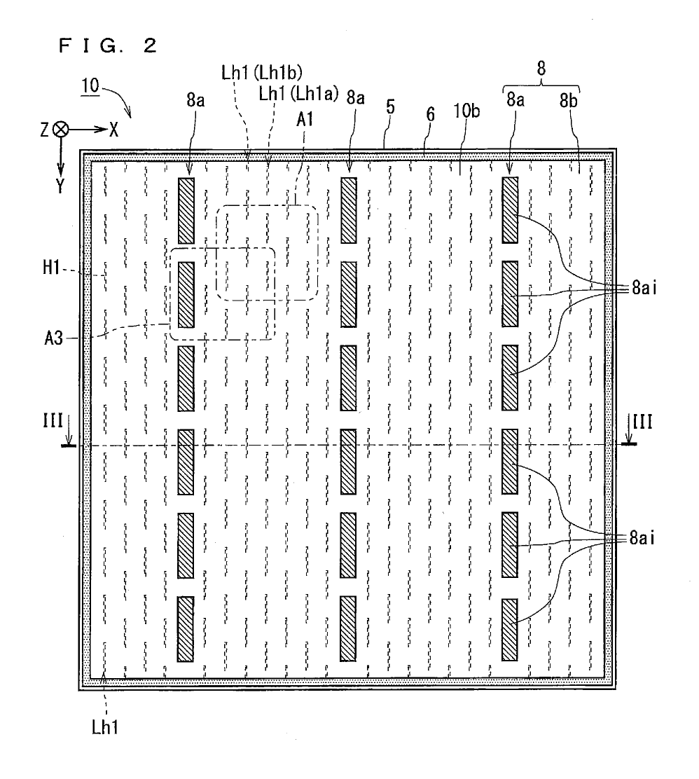

Here, when the solar cell element 10 is viewed in a plane perspective from the element back surface 10b side, there are a plurality of rows of holes (also referred to as hole rows) Lh1 each including a plurality of holes H1 positioned in a state penetrating the protective layer 6. In the example of FIG. 2, there are 22 hole rows Lh1. Each hole row Lh1 has a plurality of holes H1 positioned in a state of being arranged along the +Y direction as the first direction. In the example of FIG. 2, each hole row Lh1 has 11 or 12 holes H1. Each hole H1 includes an elongated portion along the first direction (+Y direction in the example of FIG. 2). In the example of FIG. 2, when the solar cell element 10 is viewed in a plane perspective from the back surface 10b side, each hole H1 has a belt-like (linear) shape along the first direction (+Y direction). In addition, the plurality of hole rows Lh1 are positioned in a state of being arranged in the second direction (+X direction in the example of FIG. 2) that is in a state of intersecting with the first direction (+Y direction in the example of FIG. 2). The plurality of hole rows Lh1 include a first hole row Lh1a and a second hole row Lh1b that are positioned in a mutually adjacent state in the second direction.

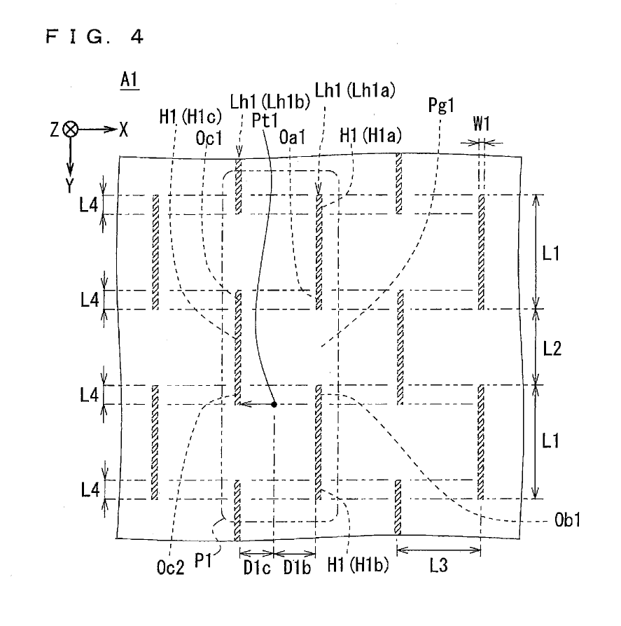

Here, as illustrated in FIG. 4, for example, a length L1 of each hole H1 in the longitudinal direction (+Y direction) is set to about 1 mm to 10 mm and a width W1 of each hole H1 in the width direction (+X direction) is set to about 0.05 mm to 0.5 mm. A pitch L3 of the hole rows Lh1 positioned adjacent to each other is set to, for example, about 0.3 mm to 3 mm. The pitch of the hole row Lh1 may be, for example, the distance between the centers of the hole rows Lh1 adjacent to each other when the solar cell element 10 is viewed in a plane perspective from the element back surface 10b side. A distance L2 between the holes H1 positioned in a mutually adjacent state in each hole row Lh1 is set to, for example, about 0.3 mm to 3 mm. The pitch of the plurality of hole rows Lh1, the distance between the holes H1, and the combination of the size, shape and number of the holes H1 can be adjusted appropriately. Therefore, for example, it is sufficient that the number of hole rows Lh1 is two or more, and the number of holes H1 in each hole row Lh1 is two or more, for example.

Meanwhile, at the time of forming a back-surface collector electrode 8b, described later, on the protective layer 6, for example, a metal paste (also referred to as an aluminum paste) containing aluminum as a main component, an organic vehicle, and glass frit is applied and fired so as to have a desired shape. At this time, the aluminum paste applied directly onto the passivation layer 4 in the hole H1 of the protective layer 6 fires through (firing penetration) the passivation layer 4 to penetrate the passivation layer 4, whereby the back-surface collector electrode 8b is directly connected to the second surface 1b of the semiconductor substrate 1. As a result, the hole H1 penetrates not only the protective layer 6 but also the passivation layer 4. At this time, for example, aluminum in the aluminum paste diffuses into the surface layer portion of the second surface 1b of the semiconductor substrate 1, whereby a third semiconductor layer 2bs is formed. Here, the main component means a component contained in the largest (highest) ratio (also referred to as content ratio).

Further, for example, the thickness of the protective layer 6 is sufficiently larger than the thickness of the passivation layer 4. Therefore, in the portion of the passivation layer 4 covered with the protective layer 6, the aluminum paste does not cause the fire-through of the passivation layer 4. Thereby, in the solar cell element 10, the passivation layer 4 can be present in a pattern corresponding to a desired pattern of the protective layer 6 on the second surface 1b of the semiconductor substrate 1. Here, for example, when the protective layer 6 is formed of silicon nitride by using a plasma-enhanced chemical vapor deposition (PECVD, plasma CVD) apparatus, the thickness of the protective layer 6 is set to, for example, about 70 nm to 200 nm. Further, for example, when the protective layer 6 is formed using an insulating paste, the thickness of the protective layer 6 is set to, for example, about 0.5 μm to 10 μm. In this case, the thickness of the protective layer 6 can be appropriately changed based on, for example, the composition of the insulating paste for forming the protective layer 6, the shape of the second surface 1b of the semiconductor substrate 1, the firing conditions at the time of forming the back-surface collector electrode 8b, and the like.

For example, the protective layer 6 is formed on the passivation layer 4 formed on the second surface 1b of the semiconductor substrate 1 by a wet process using application of an insulating paste, or a dry process using a PECVD apparatus, a sputtering apparatus, or the like. For example, an insulating paste is applied onto the passivation layer 4 so as to have a desired pattern by an application method such as a screen-printing method, which is then dried to form the protective layer 6. The insulating paste is, for example, an insulating paste containing a siloxane resin as a raw material of the protective layer 6, an organic solvent, and a plurality of fillers. The siloxane resin is a siloxane compound having a Si—O—Si bond. Specifically, it is sufficient that the siloxane resin is a low molecular weight resin having a molecular weight of 15,000 or less, which is produced by hydrolysis of alkoxysilane, silazane or the like and condensation polymerization thereof, for example. When the protective layer 6 is formed thick by applying an insulating paste or the like, it can be easily formed into a desired pattern. In addition, in this case, the hole H1 can be easily formed compared to a method such as laser beam irradiation or etching, and the process can also be simplified.

The protective layer 6 may be a thin film of silicon nitride, silicon oxide, or the like formed using the PECVD apparatus, the sputtering apparatus, or the like. In this case, a hole H1 having a desired pattern may be formed by irradiating the second surface 1b side of the semiconductor substrate 1 with a laser beam using a laser device, for example. For the laser device, a neodymium-doped yttrium-aluminum-garnet (Nd:YAG) laser with a Q switch, second harmonic (SHG) of the Nd:YAG laser, or the like can be used. As described above, when the protective layer 6 is formed by the thin film forming method, it is possible to easily form the hole H1 in both the passivation layer 4 and the protective layer 6, and it is possible to reliably connect the back-surface collector electrode 8b and the second surface 1b in the hole H1.

The protective layer 6 may be formed directly on the end face 1c of the semiconductor substrate 1, or on the antireflection layer 5 formed on the passivation layer 4, for example. In this case, a leakage current in the solar cell element 10 can be reduced by the presence of the protective layer 6.

The front-surface electrode 7 is positioned, for example, on the first surface 1a side of the semiconductor substrate 1. As illustrated in FIGS. 1 and 3, the front-surface electrode 7 includes a front-surface busbar electrode 7a and a plurality of linear front-surface collector electrodes 7b that are positioned in a state of being electrically connected to each other.

The front-surface busbar electrode 7a is an electrode (also referred to as a busbar electrode) capable of collecting carriers generated by photoelectric conversion in response to light irradiation on the semiconductor substrate 1 via the front-surface collector electrode 7b, and taking out carriers to the outside of the solar cell element 10. In the example of FIG. 1, three front-surface busbar electrodes 7a are present on the first surface 1a side of the semiconductor substrate 1. Each front-surface busbar electrode 7a has a longitudinal direction along the first surface 1a. This longitudinal direction is the +Y direction. Each front-surface busbar electrode 7a has a short side direction (also referred to as a width direction) intersecting with the longitudinal direction. The width direction is the +X direction. Here, for example, the front-surface busbar electrode 7a has an elongated rectangular shape in a plan view. The length in the lateral direction (also referred to as a width) of the front-surface busbar electrode 7a is set to, for example, about 1.3 mm to 2.5 mm. At least a part of the front-surface busbar electrode 7a is positioned in a state of intersecting with the front-surface collector electrode 7b and being electrically connected thereto.

The front-surface collector electrode 7b is an electrode (also referred to as a collector electrode) capable of collecting carriers generated by photoelectric conversion according to light irradiation on the semiconductor substrate 1. In the example of FIG. 1, a plurality of front-surface collector electrodes 7b are present on the first surface 1a side of the semiconductor substrate 1. Each front-surface collector electrode 7b has a longitudinal direction along the first surface 1a. This longitudinal direction is the +X direction. Each of the front-surface collector electrodes 7b has a transverse direction (also referred to as a width direction) intersecting with the longitudinal direction. Here, each front-surface collector electrode 7b is a linear electrode having a width of about 50 μm to 200 μm, for example. In other words, the width of each front-surface collector electrode 7b is smaller than the width of the front-surface busbar electrode 7a. The plurality of front-surface collector electrodes 7b are positioned, for example, in a state of being spaced from each other by about 1 mm to 3 mm.

The thickness of the front-surface electrode 7 is, for example, about 10 μm to 40 μm. The front-surface electrode 7 is formed by, for example, applying a metal paste (also referred to as a silver paste), which contains a metal powder containing silver as a main component and contains an organic vehicle and glass frit, in a desired shape by screen printing or the like, and then firing the paste. Further, for example, an auxiliary electrode 7c having the same shape as that of the front-surface collector electrode 7b may be positioned along the peripheral edge portion of the semiconductor substrate 1, so that the front-surface collector electrodes 7b may be electrically connected to each other.

The back-surface electrode 8 is positioned on the second surface 1b side of the semiconductor substrate 1. As illustrated in FIGS. 2 and 3, the back-surface electrode 8 includes a back-surface busbar electrode 8a and a back-surface collector electrode 8b that are positioned in a state of being electrically connected to each other.

The back-surface busbar electrode 8a is an electrode (also referred to as a busbar electrode) capable of collecting carriers generated by photoelectric conversion in response to light irradiation on the semiconductor substrate 1 via the back-surface collector electrode 8b, and taking out the carriers to the outside of the solar cell element 10. Here, for example, in the case of fabricating a solar cell module by electrically connecting a plurality of solar cell elements 10 in series, the back-surface busbar electrode 8a and the front-surface busbar electrode 7a are connected by a wiring member between the solar cell elements 10 positioned in a mutually adjacent state. Here, the wiring member is joined to, for example, the back-surface busbar electrode 8a and the front-surface busbar electrode 7a by soldering or the like.

In the example of FIG. 2, three back-surface busbar electrodes 8a are present on the second surface 1b side of the semiconductor substrate 1. Each back-surface busbar electrode 8a has a longitudinal direction along the second surface 1b. This longitudinal direction is the +Y direction. Each back-surface busbar electrode 8a includes N (N is an integer of 2 or more) island-shaped electrode portions (also referred to as island-shaped electrode portions) 8ai that are positioned in a state of being arranged along the +Y direction as a longitudinal direction. Here, the number of N is six. In other words, on the second surface 1b side of the semiconductor substrate 1, there are three rows of island-shaped electrode portions 8ai arranged in a state of being arranged along the longitudinal direction (here, the +Y direction) of the back-surface busbar electrode 8a. The back-surface busbar electrode 8a has a width direction intersecting with the longitudinal direction. This width direction is the +X direction.

The thickness of the back-surface busbar electrode 8a is set to, for example, about 10 μm to 30 μm. The width of the back-surface busbar electrode 8a is set to, for example, about 1.3 mm to 7 mm. When the back-surface busbar electrode 8a contains silver as a main component, the back-surface busbar electrode 8a is formed by, for example, applying a metal paste (also referred to as a silver paste), which contains a metal powder containing silver as a main component and contains an organic vehicle and glass frit, in a desired shape by screen printing or the like, and then firing the paste. At this time, for example, the silver paste applied directly onto the passivation layer 4 in the hole H1 of the protective layer 6 fires through the passivation layer 4 to penetrate the passivation layer 4, and therefore at least a part of the back-surface busbar electrode 8a is directly connected to the second surface 1b of the semiconductor substrate 1.

The back-surface collector electrode 8b is an electrode (also referred to as a collector electrode) capable of collecting carriers generated by photoelectric conversion according to light irradiation on the semiconductor substrate 1 on the second surface 1b side of the semiconductor substrate 1. As illustrated in FIGS. 2 and 3, the back-surface collector electrode 8b includes a first portion 8b1 and a second portion 8b2 positioned in a mutually connected state. The first portion 8b1 is positioned on the protective layer 6. The second portion 8b2 is positioned in a state of being connected to the second surface 1b in the plurality of holes H1 included in each of the plurality of hole rows Lh1. Each hole H1 is positioned in a state of penetrating the passivation layer 4 and the protective layer 6. The back-surface collector electrode 8b is positioned in a state of being electrically connected to at least a part of the back-surface busbar electrode 8a. Here, the thickness of the back-surface collector electrode 8b is set to, for example, about 15 μm to 50 μm. When the back-surface collector electrode 8b contains aluminum as a main component, the back-surface collector electrode 8b can be formed by, for example, applying the aluminum paste in a desired shape and then firing the paste.

Further, the back-surface collector electrode 8b may have a gap, for example, on the second surface 1b of the solar cell element 10, in addition to the region where the back-surface busbar electrode 8a is positioned. By application of such a structure, light incident on the second element surface 10b of the solar cell element 10 can also be used for photoelectric conversion in the solar cell element 10. In this case, for example, the output of the solar cell element 10 can be improved. Light incident on the second element surface 10b may be generated, for example, by reflection from the ground of sunlight or the like.

### 1-2. Positional Relationship Between Plurality of Holes in Plurality of Hole Rows

The positional relationship of the plurality of holes H1 in the plurality of hole rows Lh1 will be described with reference to FIGS. 4 to 6. Here, after the back-surface electrode 8 of the solar cell element 10 is removed by etching using hydrochloric acid or the like, the positions of the plurality of holes H1 can be observed with, for example, an optical microscope or a scanning electron microscope (SEM).

As illustrated in FIG. 4, when the plurality of hole rows Lh1 are viewed in a plane perspective from the second element surface 10b side, between the two hole rows Lh1 positioned in a mutually adjacent state, parts of the holes H1 in the respective hole rows Lh1 overlap each other in the first direction (here, the +Y direction) in which the plurality of holes H1 are arranged in each hole row Lh1. In the example of FIG. 4, in the first direction (+Y direction), there is a section of a length L4 in which the holes H1 overlap each other between the adjacent hole rows Lh1.

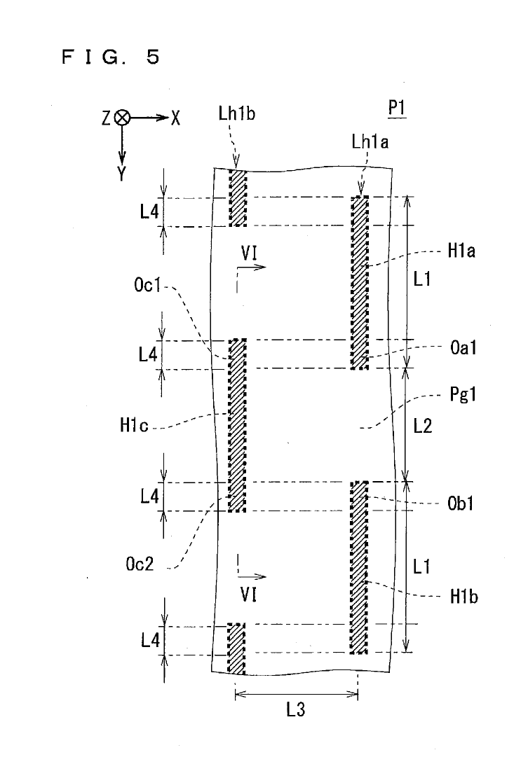

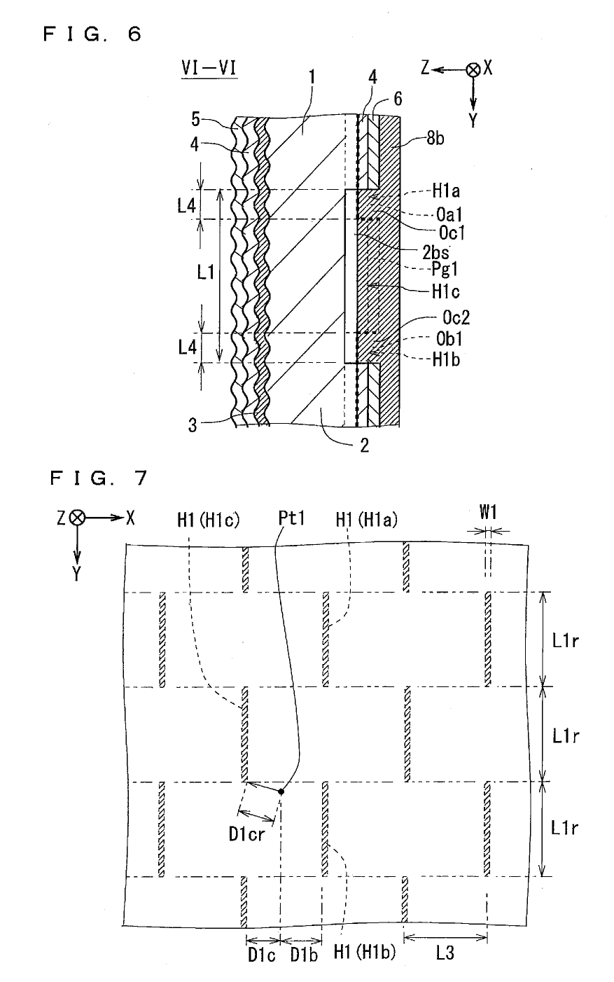

Here, as illustrated in FIGS. 4 and 5, attention is paid to the first hole row Lh1a and the second hole row Lh1b of the plurality of hole rows Lh1. In FIG. 5, the outline of each hole H1 is drawn with thick broken lines for the sake of convenience. The first hole row Lh1a includes a first hole H1a and a second hole H1b which are positioned in a mutually adjacent state. The second hole row Lh1b includes a third hole H1c. Further, it is assumed here that, as illustrated in FIG. 6, the first hole row Lh1a and the second hole row Lh1b are viewed in a plane perspective facing the second direction (here, the +X direction) in which the plurality of hole rows Lh1 are arranged. In FIG. 6, the outline of each of the first hole H1a and the second hole H1b is drawn by a thick broken line for the sake of convenience. The outline of the third hole H1c is drawn by a solid line. In this case, the third hole H1c of the second hole row Lh1b is positioned in a state of overlapping a portion (also referred to as a gap) Pg1 between the first hole H1a and the second hole H1b and further the third hole H1c is positioned in a state of overlapping a portion Oa1 of the first hole H1a and a portion Ob1 of the second hole H1b. Speaking from a different point of view, in the example of FIGS. 4 to 6, in the first direction (+Y direction), the portion Oa1 of the first hole H1a on the second hole H1b side and the portion Oc1 of the third hole H1c on the first hole H1a side are positioned in the overlapped state, and the portion Ob1 of the second hole H1b on the first hole H1a side and the portion Oc2 of the third hole H1c on the second hole H1b side are positioned in the overlapped state.

FIG. 7 illustrates an example (also referred to as a reference example) in which a part of each hole H1 does not overlap each other in the first direction (here, the +Y direction) between two hole rows positioned in the adjacent state in a portion corresponding to the portion illustrated in FIG. 4. In the example of FIG. 7, a length L1 of the hole H1 in the longitudinal direction (+Y direction) of the hole H1 has been changed to a shorter length L1r than in the example of FIG. 4, and a distance L2 between the adjacent holes H1 in each hole row has been changed to a longer length L1r than in the example of FIG. 4.

A comparison is made here between the example of FIG. 4 and the example of FIG. 7, in the distance by which a carrier generated in response to photoelectric conversion at a point Pt1 in the semiconductor substrate 1 moves within the semiconductor substrate 1 from the point Pt1 to the back-surface collector electrode 8b via the hole H1. Here, for example, a black circle indicates the point Pt1, and an arrow extending from the point Pt1 toward the hole H1 indicates a movement path of the carrier from the point Pt1 to the hole H1.

In the example of FIG. 4, the point Pt1 is positioned between the portion Ob1 of the second hole H1b and the portion Oc2 of the third hole H1c in the +X direction, and a distance D1c to the portion Oc2 is shorter a distance D1b to the portion Ob1. Therefore, the carrier can be collected by the third hole H1c that is the closest to the point Pt1. In this case, the movement distance of the carrier from the point Pt1 to the third hole H1c is the distance D1c.

On the other hand, in the example of FIG. 7, the point Pt1 is not positioned between the second hole H1b and the third hole H1c in the +X direction, but is separated by the distance D1b from the second hole H1b in the −X direction. Here, when a distance D1cr from the point Pt1 to the third hole H1e is shorter than a distance D1b from the point Pt1 to the second hole H1b, carriers can be collected by the third hole H1c closest to the point Pt1. In this case, the movement distance of the carrier from the point Pt1 to the third hole H1e is the distance D1cr. In other words, the distance D1cr in which the carrier moves from the point Pt1 to the hole H1 in the example of FIG. 7 is longer than the distance D1c in which the carrier moves from the point Pt1 to the hole H1 in the example of FIG. 4.

As described above, in the example of FIG. 4, in the region positioned between the holes H1 adjacent in the second direction (+X direction) between the mutually adjacent hole rows Lh1, the movement distance of the carrier generated by photoelectric conversion to the hole H1 can be shortened as compared with the example of FIG. 7. In this case, due to the shortening of the movement distance of the carrier, disappearance of carriers due to carrier recombination hardly occurs. Thereby, the photoelectric conversion efficiency in the PERC type solar cell element 10 can be improved. Then, for example, when a plurality of solar cell elements 10 are connected in series to form a solar cell device, components of electrical resistance related to series connection in each solar cell element 10 can be reduced. As a result, for example, the photoelectric conversion efficiency in the solar cell device can be improved.

Here, in the examples of FIGS. 2 and 4, it is assumed that the interval between the adjacent holes H1 in the first hole row Lh1a is the same as the interval between the adjacent holes H1 in the second hole row Lh1b. In this case, the sizes of the holes H1 in the plurality of hole rows Lh1 can be adjusted according to the movable distance of carrier generated in response to light irradiation in the semiconductor substrate 1. It is thereby possible to adjust ensuring the passivation effect by the passivation layer 4 and improving the collection efficiency of carriers by the back-surface collector electrode 8b in a well-balanced mariner. As a result, for example, it becomes possible to reduce the series resistance component in the equivalent circuit of the solar cell element 10, and the photoelectric conversion efficiency in the solar cell element 10 can be improved.

In the first embodiment, for example, in the case of viewing in a plane perspective in the second direction (here, the +X direction), the third hole H1c may overlap a gap Pg1 and at least one of the portion Oa1 of the first hole H1a and the portion Ob1 of the second hole H1b. Even in such a case, in the region positioned between the holes H1 adjacent to each other in the second direction (+X direction) between the hole rows Lh1 adjacent to each other, the movement distance of the carrier generated by photoelectric conversion to the hole H1 can be shortened. Thereby, for example, the photoelectric conversion efficiency in the solar cell element 10 can be improved.

### 1-3. Method for Manufacturing Solar Cell Element

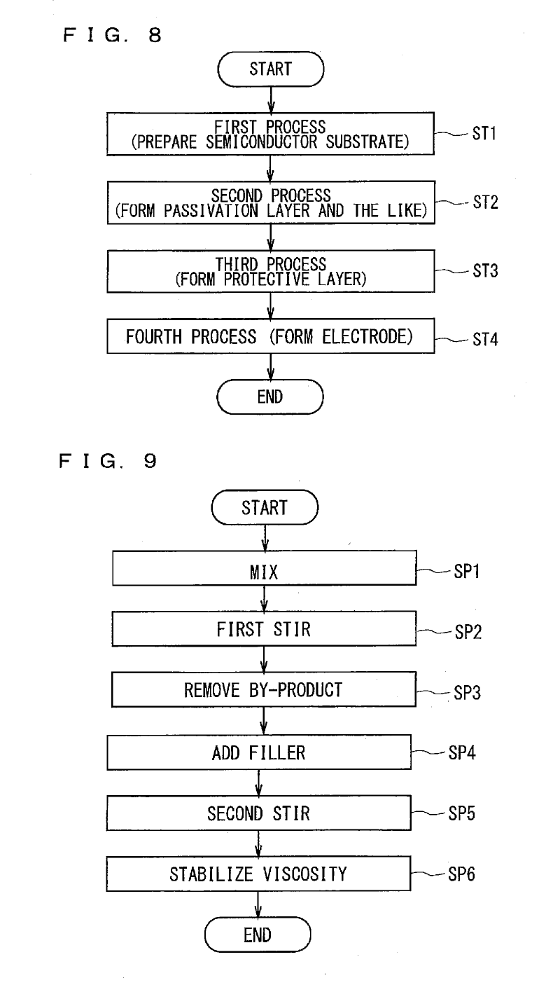

An example of a method for manufacturing the solar cell element 10 will be described with reference to FIGS. 8, 9, and 10A to 10F. Here, by performing the processes of steps ST1 to ST4 illustrated in FIG. 8 in this order, it is possible to manufacture the solar cell element 10.

### 1-3-1. Preparation of Semiconductor Substrate

In step ST1, a process of preparing the semiconductor substrate 1 (also referred to as a first process) is performed. The semiconductor substrate 1 has a first surface 1a and a second surface 1b positioned in a state of facing a direction opposite to the first surface 1a.

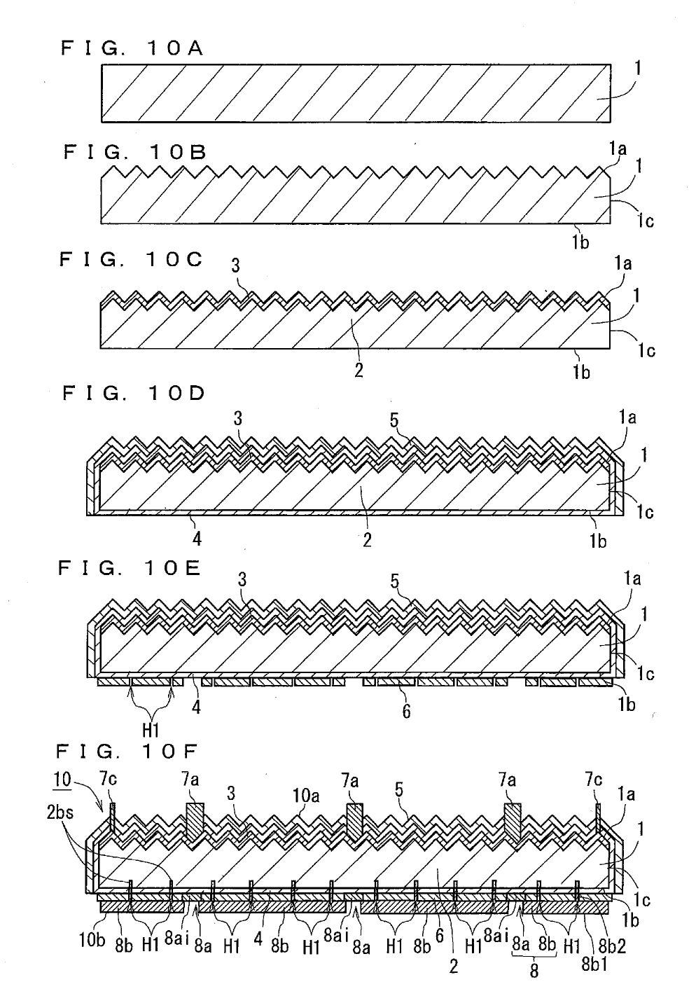

Here, first, a semiconductor substrate 1 is prepared as illustrated in FIG. 10A. The semiconductor substrate 1 can be formed using, for example, an existing CZ method, a casting method, or the like. Here, an example using a p-type polycrystalline silicon ingot prepared by the casting method will be described. The ingot is sliced to a thickness of, for example, 250 μm or smaller to prepare the semiconductor substrate 1. Here, for example, etching is slightly performed on the surface of the semiconductor substrate 1 with an aqueous solution of sodium hydroxide, potassium hydroxide, or fluoronitric acid (a mixture of hydrofluoric acid and nitric acid). It is thereby possible to remove a mechanically damaged layer and a contaminated layer of the cut surface of the semiconductor substrate 1.

Next, as illustrated in FIG. 10B, a texture is formed on the first surface 1a of the semiconductor substrate 1. The texture can be formed by wet etching using an alkaline aqueous solution such as sodium hydroxide or an acidic aqueous solution such as fluoronitric acid, or dry etching using a reactive ion etching (RIE) method or the like.

Next, as illustrated in FIG. 10C, a second semiconductor layer 3 which is an n-type semiconductor region is formed on the first surface 1a of the semiconductor substrate 1 having the texture. Specifically, the n-type second semiconductor layer 3 is formed in the surface layer portion on the first surface 1a side of the semiconductor substrate 1 having the texture. The second semiconductor layer 3 can be formed by using, for example, an application thermal diffusion method in which phosphorus is thermally diffused after applying phosphorus pentoxide (P₂O₅) in a paste state to the surface of the semiconductor substrate 1, a vapor phase thermal diffusion method in which phosphorus oxychloride (POCl₃) in a gaseous state is used as a diffusion source of phosphorus, or some other methods. The second semiconductor layer 3 is formed to have, for example, a depth of about 0.1 μm to 2 μm and a sheet resistance value of about 40 Ω/□ to 200 Ω/□.

For example, in the vapor phase thermal diffusion method, first, thermal treatment is performed on the semiconductor substrate 1 for about 5 minutes to 30 minutes at a temperature of about 600° C. to 800° C., in an atmosphere having a diffusion gas mainly containing POCl₃ or the like, to form a phosphorus glass on the surface of the semiconductor substrate 1. Thereafter, thermal treatment is performed on the semiconductor substrate 1 for about 10 minutes to 40 minutes in an atmosphere of an inert gas such as argon or nitrogen at a relatively high temperature of about 800° C. to 900° C. As a result, phosphorus is diffused from the phosphorus glass to the semiconductor substrate 1, and the second semiconductor layer 3 is formed in the surface layer portion on the first surface 1a side of the semiconductor substrate 1.

Here, at the time of forming the second semiconductor layer 3, the second semiconductor layer may be formed also on the second surface 1b side in some cases. In this case, the second semiconductor layer formed on the second surface 1b side is removed by etching. For example, by dipping a portion of the semiconductor substrate 1 on the second surface 1b side in an aqueous solution of fluoronitric acid, the second semiconductor layer formed on the second surface 1b side can be removed. As a result, a region having a p-type conductivity type can be exposed on the second surface 1b of the semiconductor substrate 1. Then, the phosphorus glass having adhered to the first surface 1a side of the semiconductor substrate 1 at the time of forming the second semiconductor layer 3 is then removed by etching. In this way, when the second semiconductor layer formed on the second surface 1b side is removed by etching with the phosphorus glass remaining on the first surface 1a side, it is possible to reduce the removal and damage of the second semiconductor layer 3 on the first surface 1a side. At this time, the second semiconductor layer formed on the end face 1c of the semiconductor substrate 1 may be removed together.

In addition, for example, a diffusion mask may be formed in advance on the second surface 1b side of the semiconductor substrate 1, the second semiconductor layer 3 may be formed by the vapor phase thermal diffusion method, and the diffusion mask may then be removed. In this case, since the second semiconductor layer is not formed on the second surface 1b side, the process of removing the second semiconductor layer on the second surface 1b side is unnecessary.

Through the above treatment, the semiconductor substrate 1 including the first semiconductor layer 2 can be prepared, in which the second semiconductor layer 3 which is an n-type semiconductor layer is positioned on the first surface 1a side and the first surface 1a has a texture.

### 1-3-2. Formation of Passivation Layer, Etc.

In step ST2, a process of forming a passivation layer 4 and the like (also referred to as a second process) is performed. In the first embodiment, at least the passivation layer 4 is formed on the second surface 1b of the semiconductor substrate 1.

Here, for example, as illustrated in FIG. 10D, the passivation layer 4 mainly containing aluminum oxide is formed on the second surface 1b of the first semiconductor layer 2 and on the first surface 1a of the second semiconductor layer 3. Further, an antireflection layer 5 is formed on the passivation layer 4. The antireflection layer 5 is made of, for example, a silicon nitride film.

The passivation layer 4 can be formed by, for example, an ALD method or the like. According to the ALD method, for example, the passivation layer 4 can be formed on the entire periphery including the end face 1c of the semiconductor substrate 1. In the process of forming the passivation layer 4 by the ALD method, first, the semiconductor substrate 1 on which the second semiconductor layer 3 is formed is placed in a chamber of a film forming device. Then, in a state where the semiconductor substrate 1 is heated to a temperature range of about 100° C. to 250° C., the following processes A to D are repeated a plurality of times to form a passivation layer 4 mainly containing aluminum oxide. Thereby, the passivation layer 4 having a desired thickness is formed.

[Process A] An aluminum raw material such as trimethylaluminum (TMA) for forming aluminum oxide is supplied onto the semiconductor substrate 1 together with a carrier gas such as argon (Ar) gas or nitrogen gas. As a result, the aluminum raw material is adsorbed to the entire periphery of the semiconductor substrate 1. The time for which TMA is supplied may be, for example, about 15 milliseconds to 3000 milliseconds. Here, at the start of the process A, the surface of the semiconductor substrate 1 is preferably terminated with an OH group. In other words, the surface of the semiconductor substrate 1 may have a structure of Si—O—H. This structure can be formed, for example, by treating the semiconductor substrate 1 with dilute hydrofluoric acid and then washing the treated substrate with pure water.

[Process B] By purifying the inside of the chamber of the film forming device with nitrogen gas, the aluminum raw material in the chamber is removed. Further, among the aluminum raw materials physically adsorbed and chemically adsorbed to the semiconductor substrate 1, the aluminum raw material except for the component chemically adsorbed at the atomic layer level is removed. The time for purifying the inside of the chamber with nitrogen gas may be, for example, about 1 second to several tens of seconds.

[Process C] An oxidizing agent such as water or ozone gas is supplied into the chamber of the film forming device, whereby the alkyl group contained in TMA is removed and substituted with the OH group. Thereby, an atomic layer of aluminum oxide is formed on the semiconductor substrate 1. The time for supplying the oxidizing agent into the chamber may be, for example, about 750 milliseconds to 1100 milliseconds. Further, for example, when hydrogen is supplied together with an oxidizing agent into the chamber, hydrogen atoms are more easily contained in aluminum oxide.

[Process D] By purifying the inside of the chamber of the film forming device with nitrogen gas, the oxidizing agent in the chamber is removed. At this time, for example, an oxidizing agent or the like which did not contribute to the reaction during the formation of aluminum oxide at the atomic layer level on the semiconductor substrate 1 is removed. Here, the time for purifying the inside of the chamber with nitrogen gas may be, for example, about 1 second to several tens of seconds.

Thereafter, a series of processes in which the process A, the process B, the process C and the process D are carried out in this order is repeated a plurality of times, whereby a layer of aluminum oxide having a desired film thickness is formed.

The antireflection layer 5 is formed by, for example, a PECVD method or a sputtering method. In the case of using the PECVD method, the semiconductor substrate 1 is previously heated to a temperature higher than the temperature during formation of the antireflection layer 5. Thereafter, a mixed gas of silane (SiH₄) and ammonia (NH₃) is diluted with nitrogen (N₂) gas to have reaction pressure of about 50 Pa to 200 Pa, and formed into plasma by glow discharge decomposition, which is then deposited on the heated semiconductor substrate 1. Thereby, the antireflection layer 5 is formed on the semiconductor substrate 1. At this time, the film forming temperature is set to about 350° C. to 650° C., and the preheating temperature of the semiconductor substrate 1 is made higher than the film forming temperature by about 50° C. In addition, a frequency of about 10 kHz to 500 kHz is adopted as a frequency of a high-frequency power source necessary for glow discharge. Further, the flow rate of the gas is appropriately determined depending on the size of the reaction chamber and the like. For example, the flow rate of the gas is in the range of about 150 ml/min (sccm) to 6000 ml/min (seem). At this time, a value (B/A) obtained by dividing a flow rate B of the ammonia gas by a flow rate A of the silane gas is in the range of 0.5 to 15.

### 1-3-3. Formation of Protective Layer

In step ST3, a process of forming a protective layer 6 (also referred to as a third process) is performed. For example, at least on the second surface 1b side of the semiconductor substrate 1, a protective layer 6 having a pattern including a portion corresponding to the hole H1 is formed on the passivation layer 4. The protective layer 6 is formed on the passivation layer 4 formed on the second surface 1b of the semiconductor substrate 1 by a wet process using solution application or the like or a dry process using PECVD, sputtering, or the like.

Here, it is assumed that the wet process using solution application or the like is adopted. In this case, at least on the second surface 1b side of the semiconductor substrate 1, a solution is applied so as to form a pattern including a portion corresponding to the hole H1 on the passivation layer 4, and this solution is dried to form the protective layer 6. At this time, for example, an insulating paste is used as a solution.

Here, for example, as illustrated in FIG. 10E, a protective layer 6 is formed on at least a part of the passivation layer 4. For example, first, the above-described insulating paste is applied to at least a part of the passivation layer 4 in a desired pattern by a screen-printing method or the like. Next, using a hot plate, a drying oven, or the like, the insulating paste after application is dried under a condition that the maximum temperature is set to about 150° C. to 350° C. and the heating time is set to about 1 minute to 10 minutes. Thereby, the protective layer 6 having a desired pattern is formed on the passivation layer 4.

### Insulating Paste

Here, for example, the insulating paste can be manufactured by performing the processes in steps SP1 to SP6 illustrated in FIG. 9 in this order.

In step SP1, there is performed a process (also referred to as a mixing process) in which a precursor of a siloxane resin is mixed with water, an organic solvent, and a catalyst in a container to prepare a mixed solution. As the precursor of the siloxane resin, for example, a silane compound having a Si—O bond, a silazane compound having a Si—N bond, or the like can be adopted. These compounds have a property (also referred to as hydrolyzability) that causes hydrolysis. In addition, the precursor of the siloxane resin is hydrolyzed to cause condensation polymerization, thereby forming a siloxane resin.

The silane compound is represented by the following general formula 1.

(R1)ₙSi(OR2)₍₄₋ₙ₎ (General Formula 1)

In the general formula 1, n is an integer of any of 0, 1, 2 and 3, for example. Further, R1 and R2 in the general formula 1 represent a hydrocarbon group such as an alkyl group (—CₘH₂ₘ₊₁) like a methyl group (—CH₃), an ethyl group (—C₂H₅) and the like, or a hydrocarbon group such as a phenyl group (—C₆H₅). Here, m is a natural number.

The silane compound contains, for example, a silane compound (also referred to as an alkyl group-based silane compound) in which at least R1 contains an alkyl group. Specifically, examples of the alkyl group-based silane compound include methyltrimethoxysilane (CH₃—Si—(OCH₃)₃) and the like. Here, for example, when the alkyl group is a methyl group, an ethyl group, or a propyl group, an alcohol can be produced as a by-product that has a small number of carbon atoms and easily volatilizes when the precursor of the siloxane resin is hydrolyzed. As a result, the by-product is easily removed in a by-product removing process described later. As a result, for example, at the time of forming the protective layer 6, generation of voids due to evaporation of the by-product hardly occurs, so that the protective layer 6 becomes dense and the barrier property of the protective layer 6 can be improved.

Also, the silane compound includes, for example, a silane compound in which R1 and R2 contain both a phenyl group and an alkyl group. Examples of such a silane compound include trimethoxyphenylsilane (C₆O₅—Si—(OCH₃)₃) and the like. For example, when a silane compound containing two or more OR bonds is adopted among the silane compounds as described above, it is possible to increase the number of siloxane bonds (Si—O—Si bond) produced by condensation polymerization of the silane compound after the hydrolysis thereof. This can lead to an increase in a network of siloxane bonds in the silicon oxide present in a state where the protective layer 6 is formed. As a result, the barrier property of the protective layer 6 can be improved.

In addition, the silazane compound may be either an inorganic silazane compound or an organic silazane compound. Here, examples of the inorganic silazane compound include polysilazane (—(H₂SiNH)—). Examples of the organic silazane compound include hexamethyldisilazane ((CH₃)₃—Si—NH—Si—(CH₃)₃) and the like.

Water is a liquid for hydrolyzing the precursor of the siloxane resin. For example, pure water is used as water. For example, water reacts with the bond of Si—OCH₃ of the silane compound to produce Si—OH bond and HO—CH₃ (methanol).

The organic solvent is a solvent for forming a paste containing a siloxane resin from a precursor of the siloxane resin. In addition, the organic solvent can mix water with the precursor of the siloxane resin. As the organic solvent, for example, diethylene glycol monobutyl ether or the like is used.

The catalyst can control the rate of the reaction when the precursor of the siloxane resin is hydrolyzed to cause condensation polymerization. For example, it is possible to adjust the rate of reaction that hydrolysis and condensation polymerization are caused in a Si—OR bond (for example, R is an alkyl group) contained in the precursor of the siloxane resin to produce Si—O—Si bond and H₂O (water) from two or more Si—OH. As the catalyst, for example, one or more inorganic acids or one or more organic acids such as hydrochloric acid, nitric acid, sulfuric acid, boric acid, phosphoric acid, hydrofluoric acid, and acetic acid are used. Also, as the catalyst, for example, one or more inorganic bases or one or more organic bases such as ammonia, sodium hydroxide, potassium hydroxide, barium hydroxide, calcium hydroxide, pyridine, and the like may be used. Further, the catalyst may be, for example, a combination of the inorganic acid and the organic acid, or a combination of the inorganic base and the organic base.

With regard to a mixing ratio of each material mixed in the mixing process, for example, in the mixed solution after mixing all the materials, the mixing ratio is adjusted such that the concentration of the precursor of the siloxane resin is 10% by mass to 90% by mass, the concentration of water is 5% by mass to 40% by mass (may also be 10% by mass to 20% by mass), the concentration of the catalyst is 1 ppm to 1000 ppm, and the concentration of the organic solvent is 5% by mass to 50% by mass. With such a mixing ratio, for example, a siloxane resin produced by hydrolysis and condensation polymerization of the precursor of the siloxane resin can be contained in the insulating paste at an appropriate concentration. In addition, for example, an excessive increase in viscosity due to gelation hardly occurs in the insulating paste.

In such a mixing process, the precursor of the siloxane resin reacts with water to initiate the hydrolysis of the precursor of the siloxane resin. In addition, the hydrolyzed precursor of the siloxane resin causes condensation polymerization, and the siloxane resin starts to be produced.

In step SP2, a process of stirring the mixed solution prepared in step SP1 (also referred to as a first stirring process) is performed. Here, the mixed solution is stirred using, for example, a mix rotor or a stirrer. When the mixed solution is stirred, further hydrolysis of the precursor of the siloxane resin proceeds. In addition, the hydrolyzed precursor of the siloxane resin causes condensation polymerization, and the siloxane resin continues to be produced. In the first stirring process, for example, heating the mixed solution facilitates hydrolysis and condensation polymerization of the precursor of the siloxane resin. Thereby, for example, the productivity can be improved by shortening the stirring time, and the viscosity of the mixed solution tends to be stabilized in processes after the first stirring process.

In step SP3, a process of removing a by-product from the mixed solution stirred in step SP2 (also referred to as a by-product removing process) is performed. In this process, for example, a by-product of an organic component containing alcohol and the like generated by the reaction of the precursor of the siloxane resin with water is volatilized. By removing this by-product, variations in viscosity of the insulating paste due to volatilization of the organic component as the by-product can be reduced when the insulating paste is stored or when the insulating paste is applied continuously. Also, when the insulating paste is applied by the screen-printing method, an emulsion of screen plate making is hardly dissolved by the organic component as the by-product. This can reduce variations in dimensions of the pattern of the screen plate making. In the by-product removing process, condensation polymerization of the precursor of the siloxane resin can be reduced, for example, by volatilizing water and the catalyst. This can reduce variations in viscosity of the mixed solution. In the by-product removing process, for example, a hot plate, a drying oven or the like is used to perform the treatment on the stirred mixed solution under the condition that the treatment temperature is from room temperature to 90° C. (may also be 50° C. to 90° C.) and the treatment time is 10 minutes to 600 minutes.

In step SP4, a process of adding a filler (also referred to as a filler adding process) is performed to the mixed solution from which by-products have been removed in step SP3. Here, for example, an inorganic filler containing silicon oxide, aluminum oxide, titanium oxide, or the like can be adopted as a filler. For example, the filler may be added to the mixed solution so that the concentration of the filler in the mixed solution after the filler has been added may also be 3% by mass to 30% by mass (may be from 5% by mass to 25% by mass). Here, it is possible to easily adjust the viscosity of the mixed solution by performing the filler adding step after the first stirring process.

In step SP5, a process of stirring the mixed solution to which the filler is added in step SP4 (also referred to as a second stirring process) is performed. Here, the mixed solution is stirred using, for example, a rotation and revolution mixer or the like. As a result, the filler can be uniformly dispersed in the mixed solution.

In step SP6, a process of stabilizing the viscosity of the mixed solution stirred in step SP5 (also referred to as a viscosity stabilizing process) is performed. Here, for example, when the mixed solution is stored at room temperature for about 2 to 24 hours, the viscosity of the mixed solution is stabilized. Thereby, an insulating paste is prepared. Here, when the viscosity of the insulating paste is adjusted, for example, to 5 Pa·sec to 400 Pa·sec when a shear rate is 1/sec, it is possible to reduce bleeding that occurs at the time of applying the insulating paste by the screen-printing method. The viscosity of the insulating paste can be measured, for example, using a viscosity-viscoelasticity measuring instrument or the like.

In the series of processes from step SP1 to step SP6 above, for example, when the viscosity of the mixed solution is stabilized in the second stirring process, the viscosity stabilizing step may be omitted. Further, for example, a filler may be added in the mixing process. In this case, the filler adding process and the second stirring process are unnecessary. Further, for example, in the case of applying the insulating paste by a spray method using a mask or the like in the case of forming the protective layer 6, it is not necessary to perform the by-product removing process. Further, for example, in the mixing process, a mixed solution containing a precursor of a siloxane resin including an alkyl group may be produced, and thereafter, in the filler addition step, a siloxane resin including a phenyl group may be added to the mixed solution.

### 1-3-4. Formation of Electrode

In step ST4 of FIG. 8, a process of forming an electrode including a front-surface electrode 7 and a back-surface electrode 8 (also referred to as a fourth process) is performed. Here, for example, a material for electrode formation is disposed on the protective layer 6 and in the hole H1 and the like, and the material for electrode formation is heated to form the back-surface electrode 8. In the first embodiment, a silver paste and an aluminum paste are adopted as the materials for electrode formation. The back-surface electrode 8 formed at this time includes a back-surface busbar electrode 8a and a back-surface collector electrode 8b. The back-surface collector electrode 8b includes a first portion 8b1 positioned on the protective layer 6, and a second portion 8b2 positioned in a state of being electrically connected to the semiconductor substrate 1 in the hole H1.

Here, for example, as illustrated in FIG. 10F, the front-surface electrode 7 and the back-surface electrode 8 are formed.

The front-surface electrode 7 is prepared using the silver paste, for example. First, the silver paste is applied to the first surface 1a side of the semiconductor substrate 1. In the first embodiment, the silver paste is applied onto the antireflection layer 5 formed on the passivation layer 4 on the first surface 1a. Here, application of the silver paste can be realized by, for example, screen printing or the like. After application of the silver paste, a solvent in the silver paste may be evaporated at a predetermined temperature to dry the silver paste. When the silver paste is to be applied by screen printing, for example, it is possible to form the front-surface busbar electrode 7a, the front-surface collector electrode 7b, and the auxiliary electrode 7c included in the front-surface electrode 7 in one process. Thereafter, for example, under the condition that the maximum temperature is 600° C. to 850° C. in a firing furnace and the heating time is set to about several tens of seconds to several tens of minutes, the front-surface electrode 7 is formed by firing the silver paste.

The back-surface busbar electrode 8a included in the back-surface electrode 8 is prepared using, for example, the silver paste. As a method for applying the silver paste to the semiconductor substrate 1, for example, a screen-printing method or the like can be used. After application of the silver paste, a solvent in the silver paste may be evaporated at a predetermined temperature to dry the silver paste. Thereafter, by firing the silver paste under the condition that the maximum temperature is 600° C. to 850° C. in the firing furnace and the heating time is several tens of seconds or longer and within about several tens of minutes, the back-surface busbar electrode 8a is formed on the second surface 1b side of the semiconductor substrate 1.

The back-surface collector electrode 8b included in the back-surface electrode 8 is prepared using, for example, the aluminum paste. First, the aluminum paste is applied to the second surface 1b side of the semiconductor substrate 1 so as to come into contact with a part of the previously applied silver paste. In the first embodiment, the aluminum paste is applied onto the protective layer 6 formed on the passivation layer 4 on the second surface 1b and into each hole H1. Here, application of the aluminum paste can be realized by, for example, screen printing or the like. Here, after the application of the aluminum paste, a solvent in the aluminum paste may be vaporized to dry the aluminum paste. Thereafter, for example, by firing the aluminum paste under the condition that the maximum temperature is 600° C. to 850° C. in the firing furnace and the heating time is set to about several tens of seconds to several tens of minutes, the back-surface collector electrode 8b is formed on the second surface 1b side of the semiconductor substrate 1. At this time, the aluminum paste causes fire-through in the passivation layer 4 and is electrically connected to the first semiconductor layer 2, whereby the back-surface collector electrode 8b is formed. Further, at this time, the third semiconductor layer 2bs is also formed along with formation of the back-surface collector electrode 8b. However, at this time, the aluminum paste on the protective layer 6 is blocked by the protective layer 6. Therefore, when the aluminum paste is fired, the passivation layer 4 blocked by the protective layer 6 is hardly affected by the firing.

In the first embodiment, for example, the back-surface busbar electrode 8a may be formed after forming the back-surface collector electrode 8b. For example, the back-surface busbar electrode 8a may be in direct contact with the semiconductor substrate 1, and the back-surface busbar electrode 8a may be not in direct contact with the semiconductor substrate 1 with, for example, the passivation layer 4 present between the back-surface busbar electrode 8a and the semiconductor substrate 1. In addition, the back-surface busbar electrode 8a may be positioned on the protective layer 6. Further, the front-surface electrode 7 and the back-surface electrode 8 may be formed by applying the respective metal pastes and then simultaneously firing the metal pastes. This can improve the productivity of the solar cell element 10. In addition, in this case, since the thermal history applied to the semiconductor substrate 1 is reduced, the output characteristics of the solar cell element 10 can be improved.

### 1-4. Summary of First Embodiment

In the solar cell element 10 according to the first embodiment, for example, when the plurality of hole rows Lh1 are viewed in a plane perspective in the second direction, between the two hole rows Lh1 adjacent to each other, there is a portion where parts of the holes H1 in the respective hole rows Lh1 overlap each other in the first direction in which the plurality of holes H1 are arranged in each hole row Lh1. For example, in the case of viewing in a plane perspective in the second direction, there is a portion where at least a part of the first hole H1a and the second hole H1b adjacent to each other in the first hole row Lh1a and a part of the third hole H1c in the second hole row Lh1b positioned in a state of being adjacent to the first hole row Lh1a overlap each other in the first direction.

Therefore, for example, in a case where the semiconductor substrate 1 is viewed in a plane perspective, when carriers generated in response to light irradiation in a portion between the hole rows Lh1 positioned in the adjacent state on the semiconductor substrate 1 are collected by the back-surface collector electrode 8b, the movement distance of the carrier can be shortened. In this case, due to the shortening of the movement distance of the carrier, disappearance of carriers due to carrier recombination hardly occurs. Thereby, the photoelectric conversion efficiency in the PERC type solar cell element 10 can be improved. Then, for example, when a plurality of solar cell elements 10 are connected in series to form a solar cell device, the components of electrical resistance related to series connection in each solar cell element 10 can be reduced. As a result, for example, the photoelectric conversion efficiency in the solar cell device can be improved.

### 2. Other Embodiments

The present disclosure is not limited to the above-described first embodiment, and various modified examples and improvements are possible without departing from the gist of the present disclosure.

### 2-1. Second Embodiment

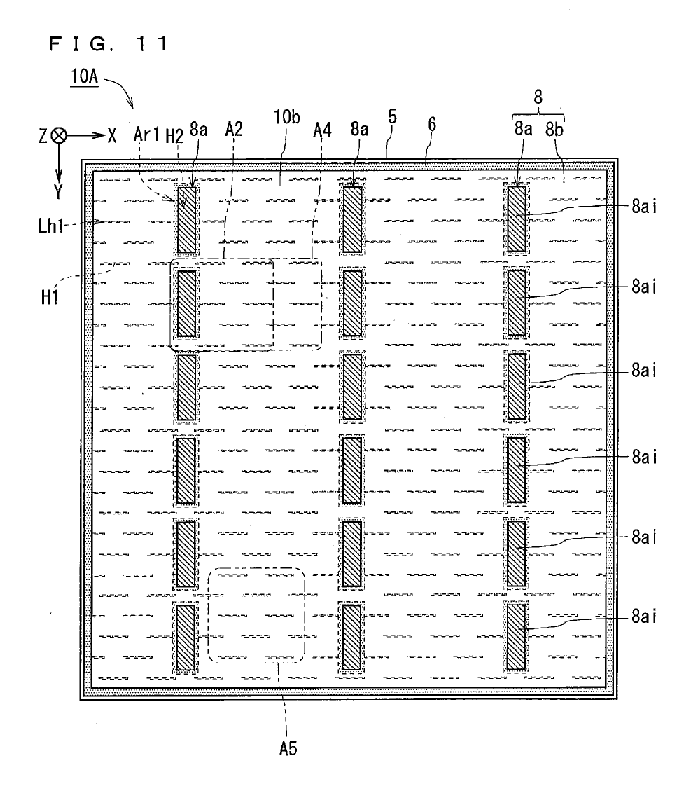

In the first embodiment, for example, the first direction in which the plurality of holes H1 are arranged in each hole row Lh1 may intersect with the longitudinal direction of the back-surface busbar electrode 8a. For example, it is conceivable that, as illustrated in FIG. 11, the longitudinal direction of the back-surface busbar electrode 8a is the +Y direction, and the first direction in which the plurality of holes H1 are arranged in each hole row Lh1 is the +X direction. Here, for example, an angle (also referred to as an intersection angle) formed by the first direction in which the plurality of holes H1 are arranged in each hole row Lh1 with respect to the longitudinal direction of the back-surface busbar electrode 8a may be larger than 0° and smaller than 180°.

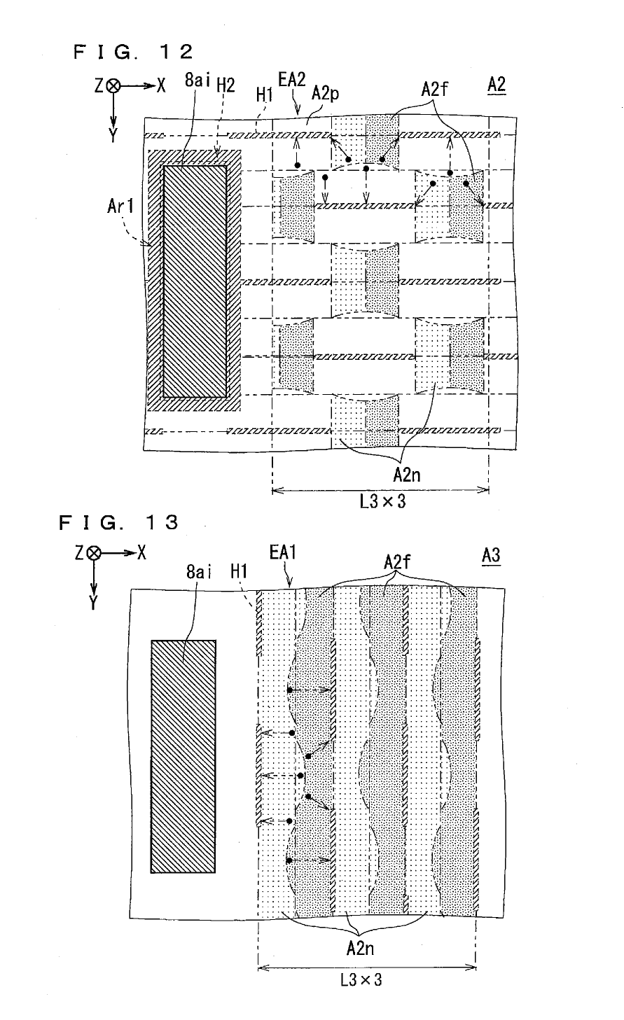

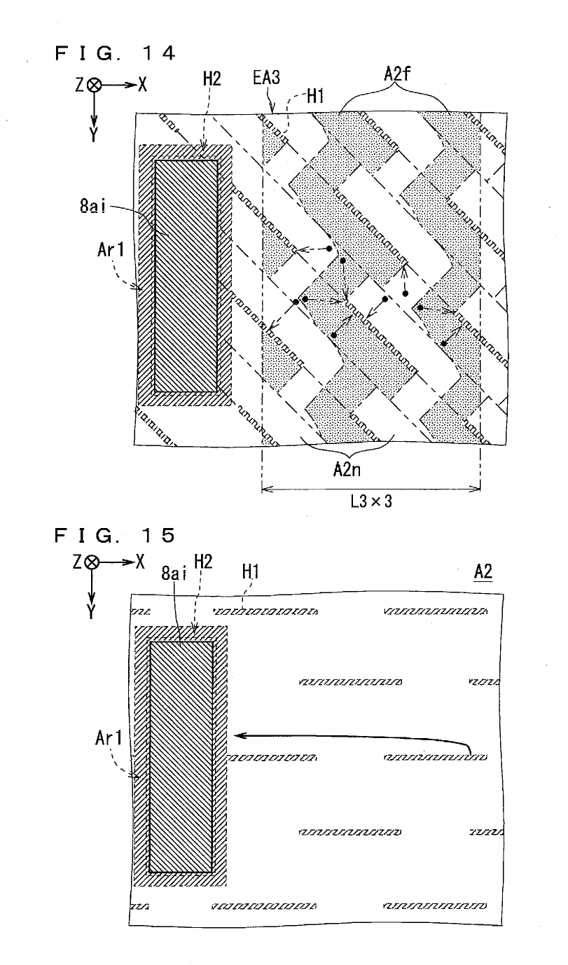

FIG. 12 illustrates a path (also referred to as a movement path) in which the carrier generated in response to light irradiation moves toward the hole H1 when collected by he back-surface collector electrode 8b in a region EA2 of the semiconductor substrate 1 in which the width is 3L×3 in the +X direction in the second region A2 in FIG. 11. FIG. 13 illustrates a movement path in which the carrier generated in response to light irradiation moves toward the hole H1 when collected by the back-surface collector electrode 8b in a region EA1 of the semiconductor substrate 1 corresponding to the region EA2 in the third region A3 in FIG. 2. In addition, FIG. 14 illustrates a movement path in which the carrier generated in response to light irradiation moves toward the hole H1 when collected by the back-surface collector electrode 8b in a region EA3 of the semiconductor substrate 1 corresponding to the region EA2 in the case of the intersection angle being 45°.

In FIGS. 12 to 14, each of the regions EA2, EA1, EA3 is divided into a region A2n, a region A2f, and a region A2p. The region A2n is a region in which the carrier generated in response to light irradiation moves to the hole H1 in a direction in which the carrier approaches the back-surface busbar electrode 8a closest to the generation position of the carrier. The region A2f is a region in which the carrier generated in response to light irradiation moves to the hole H1 in a direction in which the carrier moves away from the back-surface busbar electrode 8a closest to the generation position of the carrier. The region A2p is a region in which the carrier generated in response to light irradiation moves to the hole H1 parallel to the longitudinal direction of the back-surface busbar electrode 8a closest to the generation position of the carrier. Here, with respect to a carrier a generation position of which is indicated by a black circle, an arrow extending from the generation position toward the hole H1 indicates a movement path of the carrier from the generation position to the hole H1.

As illustrated in FIGS. 12 to 14, the first direction in which the plurality of holes H1 are arranged in each hole row Lh1 is made to intersect with the longitudinal direction of the back-surface busbar electrode 8a. As a result, in the region A2f, the distance by which the carrier moves away from the back-surface busbar electrode 8a can be shortened by the movement from the generation position of the carrier to the closest hole H1. In other words, as the intersection angle increases from 0° to 90°, for example, a long movement distance of the carrier moving from the hole H1 to the back-surface busbar electrode 8a in the back-surface collector electrode 8b can be shortened. Then, as illustrated in FIG. 12, when the intersection angle becomes 90°, the region A2f decreases and the region A2p increases. As a result, for example, as the intersection angle increases from 0° to 90°, the carrier moving from the hole H1 to the back-surface busbar electrode 8a in the back-surface collector electrode 8b tends to be equalized.

Here, for example, it is assumed that the movement distances of half of the generated carriers in the back-surface collector electrode 8b are 10 and the movement distances of the remaining half of the carriers in the back-surface collector electrode 8b are 90. In this case, for example, it is conceivable that nearly all of the carriers among the carriers having the movement distance of 10 reach the back-surface busbar electrode 8a, and almost all the carriers among the carriers having the movement distance of 90 are eliminated by recombination. On the other hand, for example, it is assumed that the movement distances of half of the generated carriers in the back-surface collector electrode 8b are 50 and the movement distances of the remaining half carriers in the back-surface collector electrode 8b are 50. In this case, it is conceivable that almost all of the carriers among the carriers having a movement distance of 50 reach the back-surface busbar electrode 8a, for example.

Therefore, for example, when the first direction in which the plurality of holes H1 are arranged in each hole row Lh1 is made to intersect with the longitudinal direction of the back-surface busbar electrode 8a, the configuration of the plurality of hole rows Lh1 can be adjusted in a direction in which the movement distances of the carriers in the back-surface collector electrode 8b is unified. Therefore, while the carrier moves from the hole H1 to the back-surface busbar electrode 8a in the back-surface collector electrode 8b, the carrier hardly disappears. This makes it possible, for example, to reduce the series resistance component in the equivalent circuit of the solar cell element 10A and realize the solar cell element 10A according to the second embodiment with improved photoelectric conversion efficiency.

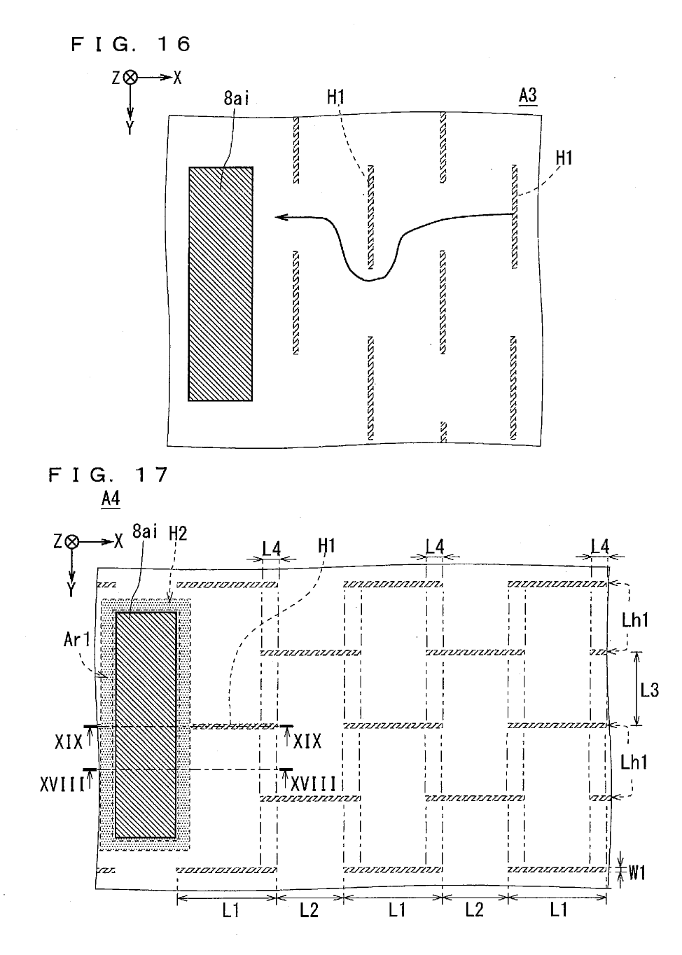

In FIG. 15, a solid arrow indicates an example of a movement path in which the carrier generated in response to light irradiation in the second region A2 in FIG. 11 moves from the hole H1 to the back-surface busbar electrode 8a in the back-surface collector electrode 8b. In FIG. 16, a solid arrow indicates a movement path in which the carrier generated in response to light irradiation in the third region A3 in FIG. 2 moves from the hole H1 to the back-surface busbar electrode 8a in the back-surface collector electrode 8b. The third region A3 is a region corresponding to the second region A2.

As described above, for example, aluminum of the aluminum paste and silicon of the semiconductor substrate 1 form an alloy during firing at the time of forming the back-surface collector electrode 8b. At this time, in the portion of the back-surface collector electrode 8b in the vicinity of the hole H1, the electrical resistance increases due to diffusion of silicon from the semiconductor substrate 1. For this reason, for example, the carrier generated in response to light irradiation in the semiconductor substrate 1 is collected by the back-surface collector electrode 8b at the hole H1, and then, while avoiding the vicinity of the hole H1 in the back-surface collector electrode 8b, the carrier moves to the back-surface busbar electrode 8a.

Here, as in the example of FIG. 16, it is assumed that the first direction in which the plurality of holes H1 are arranged in each hole row Lh1 is parallel to the longitudinal direction (+Y direction) of the back-surface busbar electrode 8a. In this case, for example, the movement path of the carrier in the back-surface collector electrode 8b can be a path taking a detour so as to avoid the other hole H1.

On the other hand, as in the example of FIG. 15, it is assumed that the first direction in which the plurality of holes H1 are arranged in each hole row Lh1 is orthogonal to the longitudinal direction (+Y direction) of the back-surface busbar electrode 8a. In this case, for example, the movement path in the back-surface collector electrode 8b of the carrier can be an almost straight path while hardly avoiding the other hole H1. Thereby, the length of the movement path of the carrier in the back-surface collector electrode 8b can be reduced. As a result, in the back-surface collector electrode 8b, disappearance of carriers due to carrier recombination hardly occurs.

Then, for example, when the first direction in which the plurality of holes H1 are arranged in each hole row Lh1 is made to intersect with the longitudinal direction of the back-surface busbar electrode 8a, there decreases a degree to which the movement path of the carrier in the back-surface collector electrode 8b takes a detour so as to avoid the other hole H1. In other words, it is possible to shorten the path in which the carrier moves from the hole H1 to the back-surface busbar electrode 8a in the back-surface collector electrode 8b. As a result, in the back-surface collector electrode 8b, disappearance of carriers due to carrier recombination hardly occurs. This makes it possible, for example, to reduce the series resistance component in the equivalent circuit of the solar cell element 10A and realize the solar cell element 10A according to the second embodiment with improved photoelectric conversion efficiency.

As the intersection angle formed by the first direction with respect to the longitudinal direction of the back-surface busbar electrode 8a increases from 0° to 90°, there can decrease a degree to which the movement path of the carrier in the back-surface collector electrode 8b takes a detour so as to avoid the other hole H1. In other words, it is possible to shorten the path in which the carrier moves from the hole H1 to the back-surface busbar electrode 8a in the back-surface collector electrode 8b. As a result, in the back-surface collector electrode 8b, disappearance of carriers due to carrier recombination hardly occurs. When the intersection angle is 90°, disappearance of carriers due to carrier recombination can be minimized.

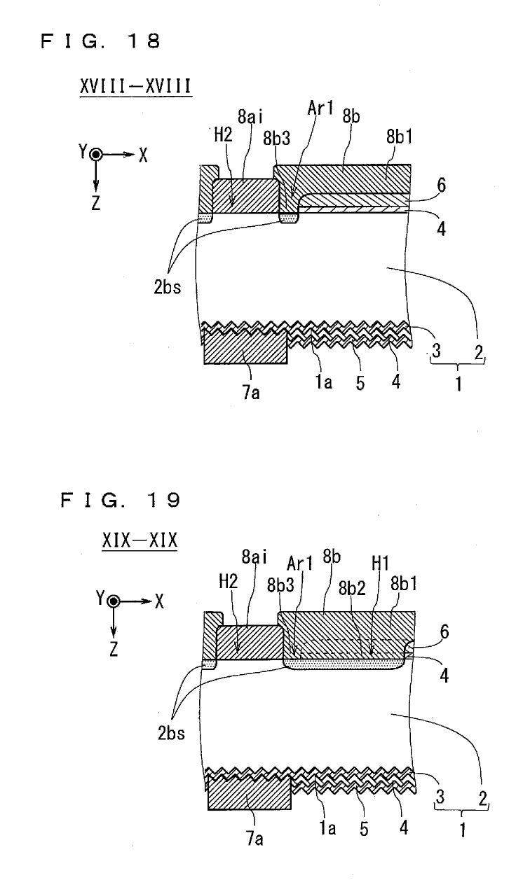

Meanwhile in the solar cell element 10A according to the second embodiment, as illustrated in FIGS. 17 and 18, for example, the back-surface busbar electrode 8a may be positioned on the second surface 1b of the semiconductor substrate 1 in a second hole H2 that is positioned in a state of penetrating the passivation layer 4 and the protective layer 6. In this case, for example, at the time of forming the protective layer 6, when the insulating paste is applied so as to have a pattern corresponding to the second hole H2, the second hole H2 can be formed. In addition, here, for example, the back-surface busbar electrode 8a may be positioned in a state of sandwiching the gap region Ar1 with the passivation layer 4 and the protective layer 6 in the width direction (here, the +X direction). In the example of FIG. 11, each island-shaped electrode portion 8ai of the back-surface busbar electrode 8a is positioned substantially in the center of the second hole H2 in a plane perspective in the +Z direction, and the periphery of each island-shaped electrode portion 8ai is surrounded by the gap region Ar1. In this case, for example, when the silver paste is applied to substantially the center of the second hole H2 of the protective layer 6 at the time of forming the back-surface busbar electrode 8a, the gap region Ar1 can be formed.

Further, for example, in the gap region Ar1, the back-surface collector electrode 8b may include a third portion 8b3 positioned in a state of connecting the first portion 8b1 positioned on the protective layer 6 and the second surface 1b of the semiconductor substrate 1. In this case, the back-surface collector electrode 8b can be connected to the second surface 1b in the vicinity of the edge on the back-surface busbar electrode 8a side of the back-surface collector electrode 8b. Thereby, for example, the adhesion of the back-surface collector electrode 8b to the semiconductor substrate 1 can be improved. As a result, for example, the reliability of the PERC type solar cell element 10 can be improved. In this case, for example, when the back-surface electrode 8 is formed, a silver paste is applied substantially at the center of the second hole H2 of the protective layer 6, and an aluminum paste is applied to the peripheral region of the silver paste in the second hole H2, the third portion 8b3 of the back-surface collector electrode 8b can be formed. At this time, for example, the third semiconductor layer 2bs can be formed at a contact portion between the third portion 8b3 of the back-surface collector electrode 8b and the semiconductor substrate 1.

Further, as illustrated in FIGS. 17 and 19, for example, the plurality of hole rows Lh1 may include one or more holes H1 positioned in a state of being linked to the gap region Ar1. In the example of FIG. 11, two holes H1 are positioned in a state of being linked to each gap region Ar1. Here, for example, when a portion positioned in one or more holes H1 of the second portion 8b2 is linked to the third portion 8b3, the back-surface collector electrode 8b can be connected to the second surface 1b in the hole H1 from the vicinity of the edge of the back-surface collector electrode 8b on the back-surface busbar electrode 8a side. Thereby, for example, the adhesion of the back-surface collector electrode 8b to the semiconductor substrate 1 can be improved. As a result, for example, the reliability of the PERC type solar cell element 10 can be improved.

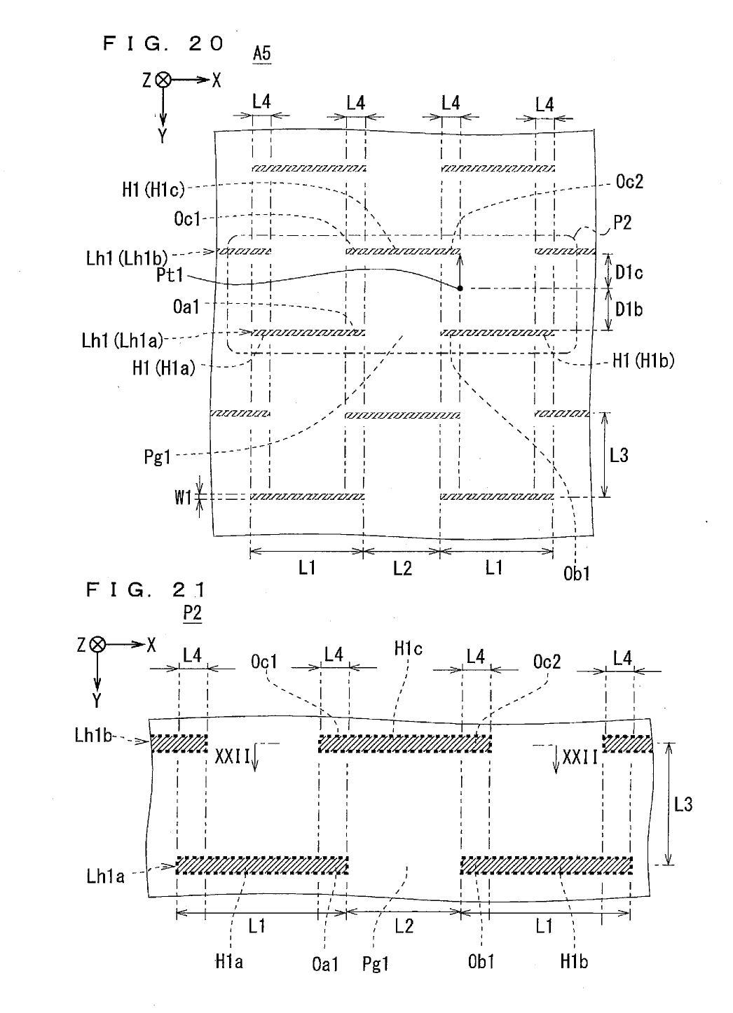

Here, also in the second embodiment, the positional relationship of the plurality of holes H1 in the plurality of hole rows Lh1 will be described with reference to FIGS. 20 to 22. Here, the positions of the plurality of holes H1 can be observed with an optical microscope or a scanning electron microscope (SEM), for example, after removal of the back-surface electrode 8 of the solar cell element 10A by etching using hydrochloric acid or the like.

As illustrated in FIG. 20, when the plurality of hole rows Lh1 are viewed in a plane perspective from the second element surface 10b side, between the two hole rows Lh1 adjacent to each other, parts of the holes H1 in the respective hole rows Lh1 overlap each other in the first direction (here, the +X direction) in which the plurality of holes H1 are arranged in each hole row Lh1. In the example of FIG. 20, in the first direction (+X direction), there is a section of a length L4 in which the holes H1 overlap each other between the adjacent hole rows Lh1.

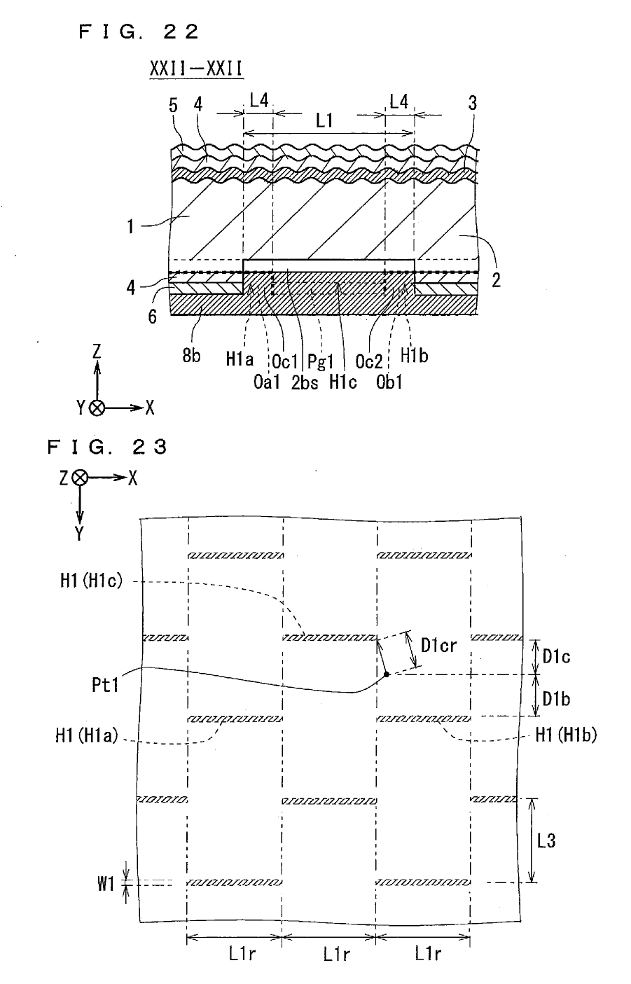

Here, as illustrated in FIGS. 20 and 21, attention is paid to the first hole row Lh1a and the second hole row Lh1b of the plurality of hole rows Lh1. In FIG. 21, the outline of each hole H1 is drawn with thick broken lines for the sake of convenience. The first hole row Lh1a includes a first hole H1a and a second hole H1b which are positioned in a mutually adjacent state. The second hole row Lh1b includes a third hole H1c. Further, it is assumed here that, as illustrated in FIG. 22, the first hole row Lh1a and the second hole row Lh1b are viewed in a plane perspective facing the second direction (here, the +Y direction) in which the plurality of hole rows Lh1 are arranged. In FIG. 22, the outline of each of the first hole H1a and the second hole H1b is drawn by a thick broken line for the sake of convenience. The outline of the third hole H1c is drawn by a solid line. In this case, the third hole H1c of the second hole row Lh1b is positioned in a state of overlapping a portion (also referred to as a gap) Pg1 between the first hole H1a and the second hole H1b and further the third hole H1c is positioned in a state of overlapping a portion Oa1 of the first hole H1a and a portion Ob1 of the second hole H1b. Speaking from a different point of view, in the example of FIGS. 20 to 22, in the first direction (+X direction), the portion Oa1 of the first hole H1a on the second hole H1b side and the portion Oc1 of the third hole H1c on the first hole H1a side are positioned in the overlapped state, and the portion Ob1 of the second hole H1b on the first hole H1a side and the portion Oc2 of the third hole H1c on the second hole H1b side are positioned in the overlapped state.

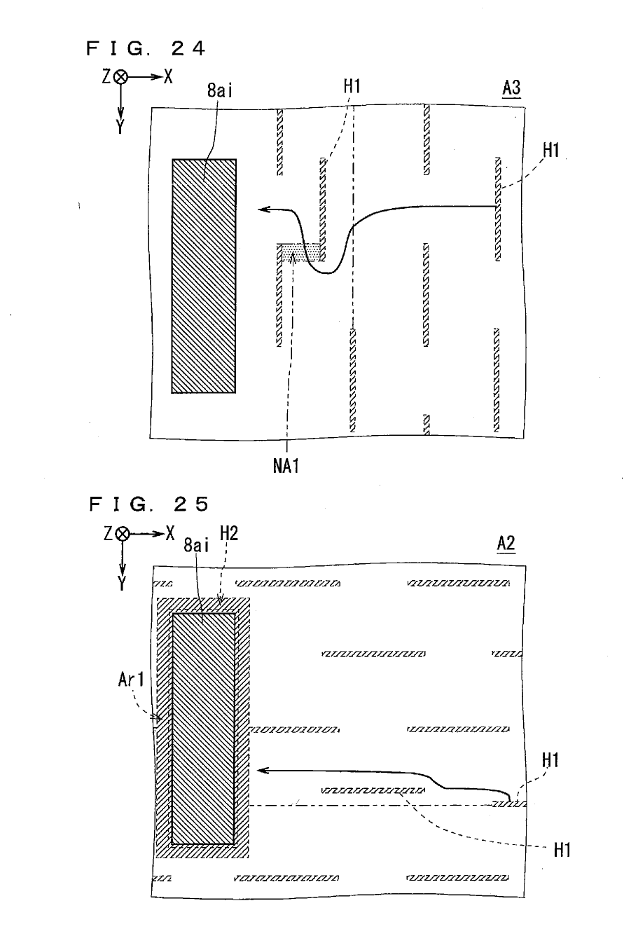

FIG. 23 illustrates an example (also referred to as a reference example) in which parts of holes H1 do not overlap each other in the first direction (here, the +X direction) between two hole rows positioned in the adjacent state in a portion corresponding to the portion illustrated in FIG. 20. In the example of FIG. 23, a length L1 of the hole H1 in the longitudinal direction (+X direction) of the hole H1 has been changed to a shorter length L1r than in the example of FIG. 20, and a distance L2 between the adjacent holes H1 in each hole row has been changed to a longer length L1r than in the example of FIG. 20.

A comparison is made here between the example of FIG. 20 and the example of FIG. 23, in the distance by which a carrier generated in response to photoelectric conversion at a point Pt1 in the semiconductor substrate 1 moves within the semiconductor substrate 1 from the point Pt1 to the back-surface collector electrode 8b via the hole H1. Here, for example, a black circle indicates the point Pt1, and an arrow extending from the point Pt1 toward the hole H1 indicates a movement path of the carrier from the point Pt1 to the hole H1.

In the example of FIG. 20, the point Pt1 is positioned between the portion Ob1 of the second hole H1b and the portion Oc2 of the third hole H1c in the +Y direction, and a distance D1c to the portion Oc2 is shorter than a distance D1b to the portion Ob1. Therefore, the carrier can be collected by the third hole H1c that is the closest to the point Pt1. At this time, the movement distance of the carrier from the point Pt1 to the third hole H1c is the distance D1c.

On the other hand, in the example of FIG. 23, the point Pt1 is not positioned between the second hole H1b and the third hole H1c in the +Y direction, but is separated by the distance D1b from the second hole H1b in the −Y direction. Here, when a distance D1cr from the point Pt1 to the third hole H1c is shorter than a distance D1b from the point Pt1 to the second hole H1b, carriers can be collected by the third hole H1c closest to the point Pt1. In this case, the movement distance of the carrier from the point Pt1 to the third hole H1c is the distance D1cr. In other words, the distance D1cr by which carriers move from the point Pt1 to the hole H1 in the example of FIG. 23 is longer than the distance D1c from the point Pt1 to the hole H1 in the example of FIG. 20.

As described above, in the example of FIG. 20, in a region positioned between adjacent holes H1 in the second direction (+Y direction) between adjacent hole rows Lh1, the movement distance until the carrier generated by photoelectric conversion reaches the hole H1 can be shortened as compared with the example of FIG. 23. In this case, due to the shortening of the movement distance of the carrier, disappearance of carriers due to carrier recombination hardly occurs. Thereby, the photoelectric conversion efficiency in the PERC type solar cell element 10A can be improved. Then, for example, when a plurality of solar cell elements 10A are connected in series to form a solar cell device, the components of electrical resistance related to series connection in each solar cell element 10A can be reduced. As a result, for example, the photoelectric conversion efficiency in the solar cell device can be improved.

Here, in the examples of FIGS. 11 and 20, it is assumed that the interval between the adjacent holes H1 in the first hole row Lh1a is the same as the interval between the adjacent holes H1 in the second hole row Lh1b. In this case, the sizes of the holes H1 in the plurality of hole rows Lh1 can be adjusted according to the movable distance of carrier generated in response to light irradiation in the semiconductor substrate 1. It is thereby possible to adjust ensuring the passivation effect by the passivation layer 4 and improving the collection efficiency of carriers by the back-surface collector electrode 8b in a well-balanced manner. As a result, for example, it becomes possible to reduce the series resistance component in the equivalent circuit of the solar cell element 10A, and the photoelectric conversion efficiency in the solar cell element 10A can be improved.

In the second embodiment, for example, in the case of viewing in a plane perspective in the second direction (here, the +Y direction), the third hole H1c may overlap a gap Pg1 and at least one of the portion Oa1 of the first hole H1a and the portion Ob1 of the second hole H1b. Even in such a case, in the region positioned between the holes H1 adjacent to each other in the second direction (+Y direction) between the hole rows Lh1 adjacent to each other, the movement distance of the carrier generated by photoelectric conversion to the hole H1 can be shortened. Thereby, for example, the photoelectric conversion efficiency in the solar cell element 10 can be improved.

Here, for example, the cross section of the solar cell element 10A can be observed by SEM, after cutting of the solar cell element 10A and removal of a portion having distortion and scratches due to the cutting by etching using hydrochloric acid or the like.

### 3. Others

In each of the above-described embodiments, for example, in each hole row Lh1, the plurality of holes H1 are positioned in a state of being arranged along the first direction, but may include one or more holes H1 slightly shifted in the second direction that is in a state of intersecting with the first direction. However, for example, in the first embodiment, as illustrated in FIG. 24, when the two holes H1 are too close between the hole rows Lh1 positioned in a mutually adjacent state, the electrical resistance in a region NA1 between the two holes H1 in the back-surface collector electrode 8b can be increased by diffusion of silicon from the semiconductor substrate 1. In this case, for example, due to the presence of the region NA1 in which the electrical resistance is increased, movement of carriers in the back-surface collector electrode 8b can be hindered. Therefore, for example, in each hole row Lh1, one or more holes H1 among the plurality of holes H1 positioned in a state of being arranged along the first direction may be slightly shifted in a second direction that is in a state of intersecting with the first direction within a range not too close to the hole H1 in an adjacent hole row Lh1. Further, for example, in the second embodiment, as illustrated in FIG. 25, when some of the holes H1 among the plurality of holes H1 are shifted in the second direction that is in a state of intersecting with the first direction in the hole row Lh1, the length of the movement path of the carrier in the back-surface collector electrode 8b can be increased so as to avoid the vicinity of the hole H1. Therefore, in each hole row Lh1, for example, when a plurality of holes H1 are positioned in a state of being arranged in a straight line along the first direction, the length of the of movement path of the carrier in the back-surface collector electrode 8b can be reduced. As a result, in the back-surface collector electrode 8b, disappearance of carriers due to carrier recombination hardly occurs.

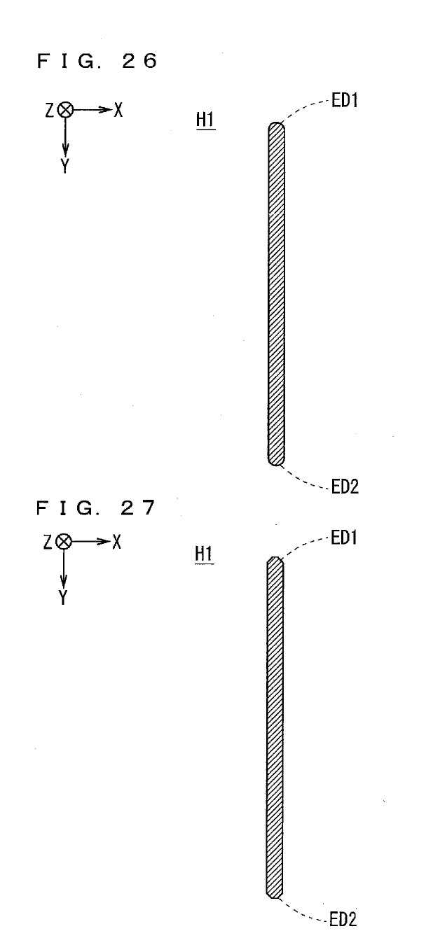

In the above embodiments, for example, as illustrated in FIG. 26, the elongated portion of the hole H1 may include ends ED1, ED2 each including a corner positioned in a state where the inner surface has a curved surface in the first direction in which the plurality of holes H1 are arranged in each hole row Lh1. Further, for example, as illustrated in FIG. 27, the elongated portion of the hole H1 may include ends ED1, ED2 each including a corner positioned in a state where the inner surface has an obtuse angle in the first direction in which the plurality of holes H1 are arranged in each hole row Lh1. In other words, for example, the elongated portion of the hole H1 may include the ends ED1, ED2 each including at least one of a corner that is positioned in a state where the inner surface forms an obtuse angle and a corner positioned in a state where the inner surface has a curved surface in the first direction. With such a configuration, for example, it becomes easier to fill each hole H1 with a conductive paste for forming the back-surface collector electrode 8b. This enables, for example, an increase in an area where the front surface of the semiconductor substrate 1 and the back-surface collector electrode 8b are connected. As a result, for example, the electrical resistance with respect to the collection of carriers generated in response to light irradiation in the semiconductor substrate 1 can be reduced. As a result, the photoelectric conversion efficiency in the PERC type solar cell elements 10, 10A can be improved.

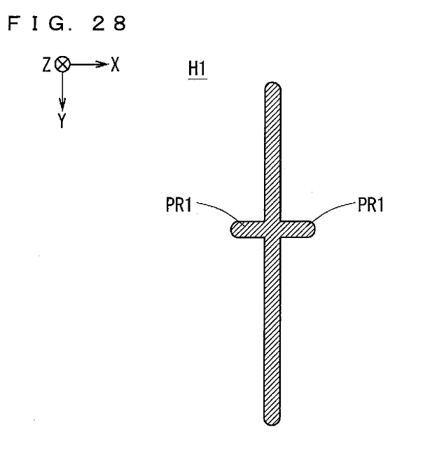

In each of the above embodiments, for example, as illustrated in FIG. 28, the hole H1 may have a portion PR1 protruding in a direction that intersects with the first direction in addition to the elongated portion along the first direction.

In each of the above embodiments, for example, the longitudinal directions of the plurality of back-surface busbar electrodes 8a may be slightly different from each other.

In each of the above embodiments, for example, the back-surface busbar electrode 8a may be formed of one elongated portion along the longitudinal direction. In other words, for example, the back-surface busbar electrode 8a may be one or more portions along the longitudinal direction.

It goes without saying that all or a part of each of the embodiments and each of the modified examples can be combined as appropriate in a range not contradictory.

1. A solar cell element comprising:
a semiconductor substrate having a first surface and a second surface opposite the first surface;
a passivation layer positioned on the second surface;
a protective layer positioned on the passivation layer; and
a collector electrode including a first portion on the protective layer, and a second portion positioned in a state of being connected to the second surface in a plurality of hole rows, each of which includes a plurality of holes that are positioned in a state of penetrating the passivation layer and the protective layer,
wherein in each of the hole rows, the plurality of holes are positioned in a state of being arranged along a first direction,
each of the holes includes an elongated portion along the first direction,
the plurality of hole rows include a first hole row and a second hole row that are positioned while adjacent to each other in a second direction that is in a state of intersecting with the first direction,
the first hole row includes a first hole and a second hole that are positioned in a mutually adjacent state, and
when the first hole row and the second hole row are viewed in a plane perspective facing the second direction, the second hole row includes a third hole positioned in a state of overlapping a gap between the first hole and the second hole and further positioned in a state of overlapping a part of at least one of the first hole and the second hole.

2. The solar cell element according to claim 1, further comprising a busbar electrode that is positioned on the second surface side, while positioned in a state of being electrically connected to the collector electrode, and has a longitudinal direction along the second surface,
wherein the first direction intersects with the longitudinal direction.

3. The solar cell element according to claim 1, wherein an interval between the holes that are positioned in a mutually adjacent state in the first hole row is the same as an interval between the holes that are positioned in a mutually adjacent state in the second hole row.

4. The solar cell element according to claim 2, wherein
the busbar electrode has a width direction intersecting with the longitudinal direction, and is positioned in a state of sandwiching a gap region with the passivation layer and the protective layer,
the plurality of hole rows include one or more holes that are positioned in a state of being linked to the gap region,
the collector electrode includes a third portion that is positioned in a state of connecting the first portion and the second surface in the gap region, and
a portion positioned in the one or more holes in the second portion and the third portion are positioned in a mutually linked state.

5. The solar cell element according to claim 1, wherein the elongated portion includes, in the first direction, an end having at least one of a corner that is present in a state where an inner surface forms an obtuse angle and a corner positioned in a state where an inner surface has a curved surface.

6. A solar cell element comprising:
a semiconductor substrate having a first surface and a second surface opposite the first surface;
a passivation layer positioned on the second surface;
a protective layer positioned on the passivation layer;
a collector electrode including a first portion on the protective layer, and a second portion positioned in a state of being connected to the second surface in a plurality of hole rows, each of which includes a plurality of holes that are positioned in a state of penetrating the passivation layer and the protective layer; and
a busbar electrode that is positioned on the second surface side, while positioned in a state of being electrically connected to the collector electrode, and has a longitudinal direction along the second surface,
wherein in each of the hole rows, the plurality of holes are positioned in a state of being arranged along a first direction that is in a state of intersecting with the longitudinal direction,
each of the holes includes an elongated portion along the first direction, and
the plurality of hole rows are positioned while arranged in a second direction that is in a state of intersecting with the first direction.

7. The solar cell element according to claim 6, wherein
the plurality of hole rows include a first hole row and a second hole row that are positioned in a mutually adjacent state in the second direction,
the first hole row includes a first hole and a second hole that are positioned in a mutually adjacent state, and
when the first hole row and the second hole row are viewed in a plane perspective facing the second direction, the second hole row includes a third hole positioned in a state of overlapping a gap between the first hole and the second hole and further positioned in a state of overlapping a part of at least one of the first hole and the second hole.

8. The solar cell element according to claim 7, wherein an interval between the holes that are positioned in a mutually adjacent state in the first hole row is the same as an interval between the holes that are positioned in a mutually adjacent state in the second hole row.

9. The solar cell element according to claim 6, wherein
the busbar electrode has a width direction intersecting with the longitudinal direction, and is positioned in a state of sandwiching a gap region with the passivation layer and the protective layer,
the plurality of hole rows include one or more holes that are positioned in a state of being linked to the gap region,
the collector electrode includes a third portion that is positioned in a state of connecting the first portion and the second surface in the gap region, and
a portion positioned in the one or more holes in the second portion and the third portion are positioned in a mutually linked state.

10. The solar cell element according to claim 6, wherein the elongated portion includes, in the first direction, an end having at least one of a corner that is present in a state where an inner surface forms an obtuse angle and a corner positioned in a state where an inner surface has a curved surface.
